(19) United States
(12) Patent Application Publication
(10) Pub. No.: US 2013/0048369 A1
(43) Pub. Date: Feb. 28, 2013

(54) SYSTEMS AND METHODS FOR SHIELDING CIRCUITRY FROM INTERFERENCE WITH A REMOVABLE SHIELD ASSEMBLY

(71) Applicants: Shayan Malek, San Jose, CA (US); Gregory Stephens, Sunnyvale, CA (US); Jared Mitchell Kole, San Jose, CA (US); Richard Hung Minh Dinh, San Jose, CA (US); Robert Sorensen, Fremont, CA (US)

(72) Inventors: Shayan Malek, San Jose, CA (US); Gregory Stephens, Sunnyvale, CA (US); Jared Mitchell Kole, San Jose, CA (US); Richard Hung Minh Dinh, San Jose, CA (US); Robert Sorensen, Fremont, CA (US)

(73) Assignee: APPLE INC., Cupertino, CA (US)

(21) Appl. No.: 13/222,179

(22) Filed: Aug. 31, 2011

(51) Int. Cl. H05K 9/00; H05K 13/00

(52) U.S. Cl. 174/377; 29/592.1

(57) ABSTRACT

This is directed to systems and methods for shielding a circuitry region of an electronic device from interference (e.g., EMI) with a removable shield assembly.

### FIELD OF THE INVENTION

This can relate to systems and methods for shielding circuitry from interference and, more particularly, to systems and methods for shielding circuitry from interference with a removable shield assembly.

### BACKGROUND OF THE DISCLOSURE

Electromagnetic interference (“EMI”) and radio frequency interference (“RFI”) are two of the various types of unwanted disturbances that may interrupt, obstruct, or otherwise affect or limit the effective performance of electronic circuitry due to electromagnetic conduction or electromagnetic radiation from an external source. One way to reduce such interference for electronic circuitry is to place electrically conducting metal around the circuitry. For example, an electronic circuit component on a circuit board is sometimes placed under a metal cover or can. A possible problem with the foregoing approach is that the metal shielding is typically soldered or otherwise fixed to the circuit board about the circuit component, such that, once the shielding is mounted to the circuit board, the circuit component cannot be physically accessed without removing the shielding.

### SUMMARY OF THE DISCLOSURE

Systems and methods for shielding circuitry from interference with a removable shield assembly are provided.

According to some embodiments, there may be provided a shield assembly that may include a shield fence and a shield lid. The shield fence may include a fence body having a fence body coupling feature. The shield fence may also include a fence finger extending from the fence body and having a fence finger coupling feature. The shield lid may include a lid body having a lid body coupling feature that may interact with the fence body coupling feature to create a first ground point when the shield fence is coupled to the shield lid. The shield lid may also include a lid finger extending from the lid body and having a lid finger coupling feature that interacts with the fence finger coupling feature to create a second ground point when the shield fence is coupled to the shield lid. For example, a set of ground points including at least the at least the first ground point and the second ground point may be created when the shield fence is coupled to the shield lid. The set of ground points may define a closed loop of ground points, and each ground point of the set of ground points may be separated by less than a threshold distance from each of the two ground points adjacent to the ground point in the closed loop.

In some embodiments, for example, the shield lid may be fixedly attached to a circuit board (e.g., using solder or screws or other techniques that may require tools to remove the lid from the circuit board or that may require impairing the elements that had coupled the shield lid to the circuit board), while the shield lid may be removably coupled to the shield fence. For example, a lid finger coupling feature may interact with a fence finger coupling feature to maintain the relative positions of the shield and lid when coupled together, but the shield and lid may be unattached from one another without impairing or breaking the lid finger coupling feature or the fence finger coupling feature (e.g., the interacting finger coupling features may be a protrusion that may be biased to snap into and out of a respective hole).

According to some other embodiments, there may be provided a system that may include a circuit board, a circuitry region coupled to a top surface of the circuit board, a shield fence coupled to the top surface of the circuit board, and a shield lid. The shield fence may include a fence body having a fence body coupling feature. The shield fence may also include a fence finger extending from the fence body and having a fence finger coupling feature. The shield lid may include a lid body having a lid body coupling feature that may interact with the fence body coupling feature when the shield fence is coupled to the shield lid. The shield lid may also include a lid finger extending from the lid body and having a lid finger coupling feature that may interact with the fence finger coupling feature when the shield fence is coupled to the shield lid. For example, the lid body coupling feature may interact with the fence body coupling feature to restrict the movement of the shield fence with respect to the shield lid in at least one direction when the shield fence is coupled to the shield lid, such as in at least one direction that is parallel to the top surface of the circuit board, the fence body, or the lid body. As another example, the lid finger coupling feature may interact with the fence finger coupling feature to restrict the movement of the shield fence with respect to the shield lid in at least one direction when the shield fence is coupled to the shield lid, such as in at least one direction that is perpendicular to the top surface of the circuit board, the fence body, or the lid body.

According to yet some other embodiments, there may be provided a method for shielding a circuitry region. The method may include providing a shield fence that may have a fence body and a fence finger extending away from the fence body. The method may also include providing a shield lid that may have a lid body and a lid finger extending away from the lid body. The method may also include positioning the fence body above the circuitry region such that the fence finger may extend down from the fence body and adjacent to the circuitry region. Moreover, the method may then include positioning the lid body above the fence body such that the lid finger may extend down from the lid body and adjacent to the fence finger, such that a fence body coupling feature of the fence body may interact with a lid body coupling feature of the lid body, and such that a fence finger coupling feature of the fence finger may interact with a lid finger coupling feature of the lid finger.

### BRIEF DESCRIPTION OF THE DRAWINGS

The above and other aspects of the invention, its nature, and various features will become more apparent upon consideration of the following detailed description, taken in conjunction with the accompanying drawings, in which like reference characters refer to like parts throughout, and in which:

FIG. 1 is an isometric view of a portion of an electronic device and a shield assembly, in a first stage of assemblage, in accordance with some embodiments of the invention;

FIG. 2 is an isometric view, similar to FIG. 1, of the portion of the electronic device and the shield assembly of FIG. 1, in a second stage of assemblage, in accordance with some embodiments of the invention;

FIG. 3 is an isometric view, similar to FIGS. 1 and 2, of the portion of the electronic device and the shield assembly of FIGS. 1 and 2, in a third stage of assemblage, in accordance with some embodiments of the invention;

FIG. 4 is a partial cross-sectional view of the portion of the electronic device and the shield assembly of FIGS. 1-3, taken from line IV-IV of FIG. 3;

FIG. 5 is a partial cross-sectional view of the portion of the electronic device and the shield assembly of FIGS. 1-4, taken from line V-V of FIG. 3;

FIG. 6 is a partial cross-sectional view of the portion of the electronic device and the shield assembly of FIGS. 1-5, taken from line VI-VI of FIG. 3;

FIG. 7 is a partial cross-sectional view of the portion of the electronic device and the shield assembly of FIGS. 1-6, taken from line VII-VII of FIG. 3;

FIG. 8 is an isometric view of a shield fence, in accordance with some embodiments of the invention;

FIG. 9 is an isometric view of a shield lid, in accordance with some embodiments of the invention;

FIG. 10 is an isometric view, similar to FIG. 8, of the shield fence of FIG. 8 coupled to the shield lid of FIG. 9 and a portion of the electronic device of FIGS. 1-7 for forming a shield assembly, in accordance with some embodiments of the invention;

FIG. 11 is an isometric view, similar to FIG. 9, of the shield assembly of FIG. 10, in accordance with some embodiments of the invention;

FIG. 12 is a partial cross-sectional view of the shield assembly of FIGS. 10 and 11, taken from line XII-XII of FIG. 10;

FIG. 12A is a detailed view of the portion of the shield assembly of FIGS. 10-12 identified by the loupe XIIA of FIG. 12; and

FIG. 13 is a flowchart of an illustrative process for shielding a circuitry region, in accordance with some embodiments of the invention.

### DETAILED DESCRIPTION OF THE DISCLOSURE

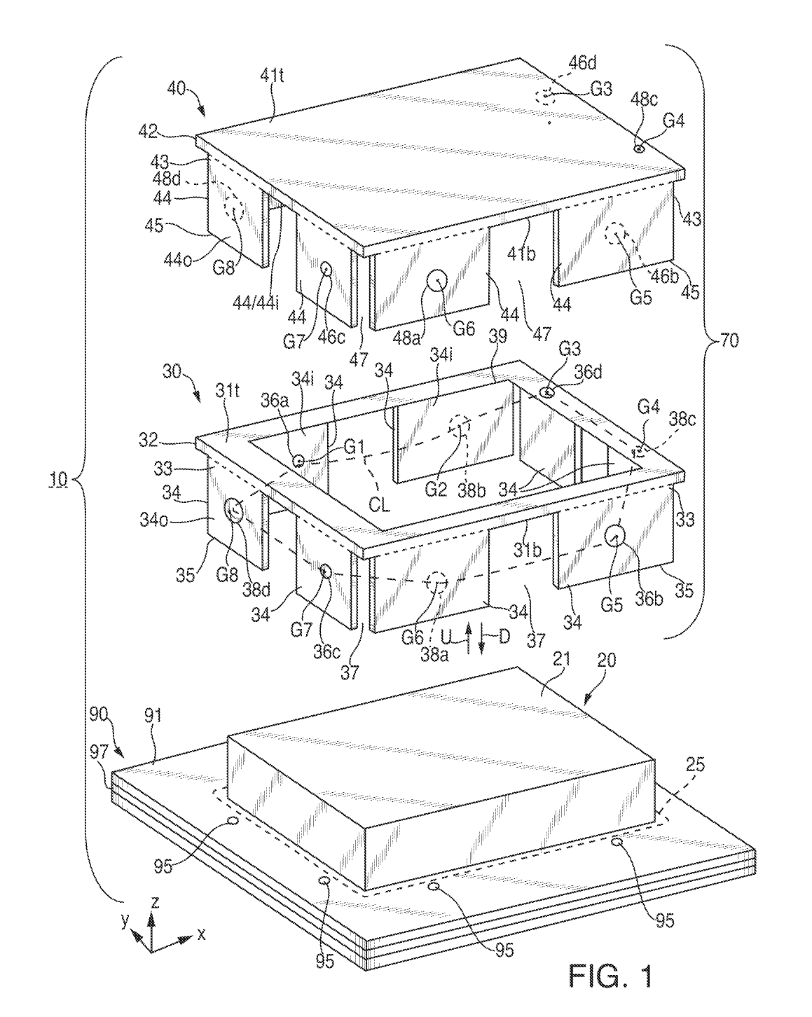

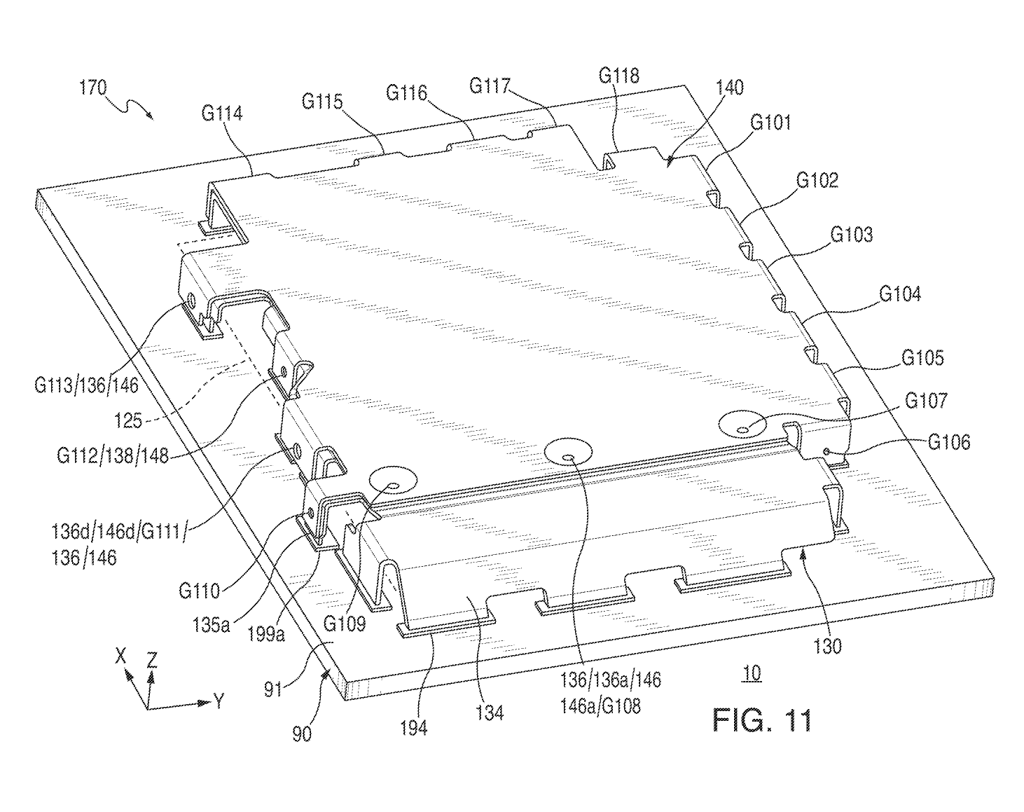

Systems and methods for shielding circuitry from interference with a removable shield assembly are provided and described with reference to FIGS. 1-13.

FIGS. 1-7, for example, show various portions of an exemplary electronic device 10 that may include an electronic component 20. Electronic component 20 may be coupled to a circuit board 90 and may be shielded by a shield assembly 70. The term “electronic device” can include, but is not limited to, music players, video players, still image players, game players, other media players, music recorders, video recorders, cameras, other media recorders, radios, medical equipment, domestic appliances, transportation vehicle instruments, musical instruments, calculators, cellular telephones, other wireless communication devices, personal digital assistants, remote controls, pagers, computers (e.g., desktops, laptops, tablets, servers, etc.), monitors, televisions, stereo equipment, set up boxes, set-top boxes, boom boxes, modems, routers, keyboards, mice, speakers, printers, and combinations thereof.

As shown in FIGS. 1-7, for example, electronic device 10 may include circuit board 90 and electronic component 20. Circuit board 90 may be a central or primary printed circuit board (“PCB”) of electronic device 10, and may also be known as a main circuit board, motherboard, mainboard, baseboard, system board, planar board, or logic board. Circuit board 90 may provide one or more attachment points to electronic component 20 of electronic device 10. Although FIGS. 1-7 only show one electronic component (i.e., component 20) coupled to circuit board 90, in other embodiments, two or more electronic components may be provided on circuit board 90 of electronic device 10. Generally, most of the basic circuitry and components required for electronic device 10 to function may be onboard or coupled (e.g., via one or more cables, bond pads, leads, terminals, cables, wires, contact regions, etc.) to circuit board 90. For example, electronic component 20 may be mounted or otherwise coupled to a top surface 91 of circuit board 90. Electronic component 20 may include one or more chipsets or specialized groups of integrated circuits. For example, circuit board 90 may include two components or chips, such as a Northbridge and

Southbridge. Although in other embodiments, these chips may be combined into a single component. Electronic component 20 can also be one of various other types of component, including, but not limited to, a processor, memory, power supply, communications circuitry, input component, output component, and combinations thereof.

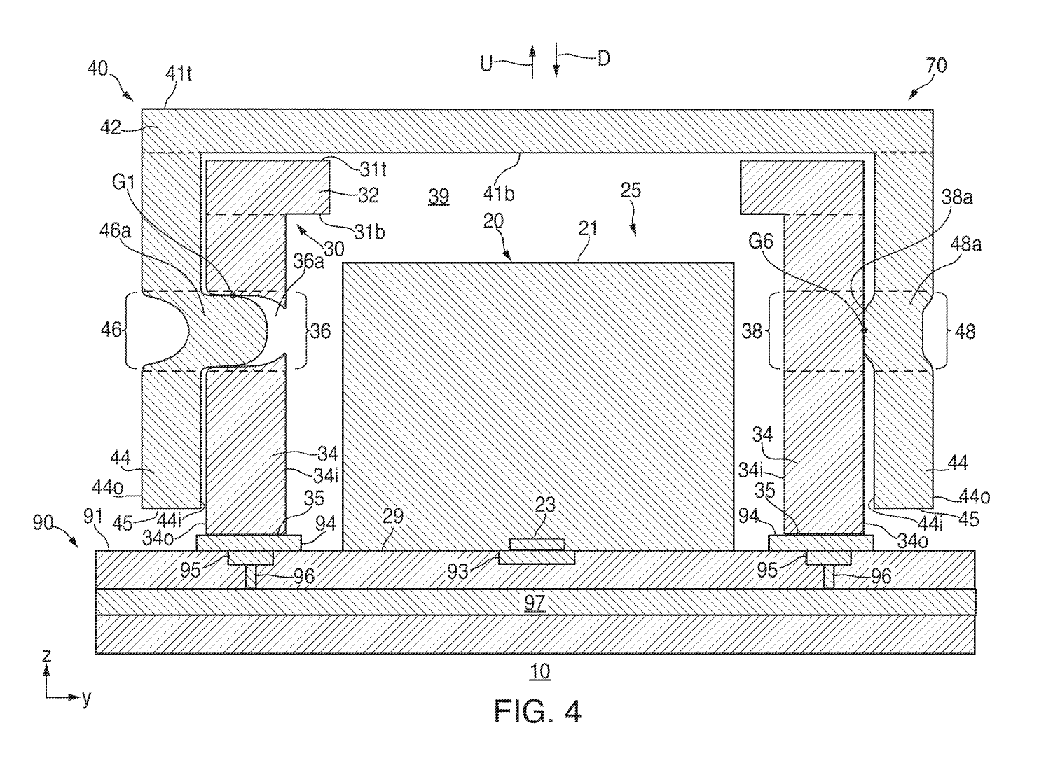

As shown in FIGS. 1-7, for example, electronic component 20 may include a top surface 21, a bottom surface 29, and at least one terminal or bond pad or other component contact region 23 coupled to circuitry (not shown) of electronic component 20. Each component contact region 23 of electronic component 20 may also be electrically coupled to a respective terminal, bond pad, or other type of board contact region 93 of circuit board 90. Each board contact region 93 of circuit board 90 may also be coupled to one or more signal planes, vias, or other circuitry (not shown) of circuit board 90. For example, as shown in FIGS. 4-7, electronic component 20 may include component contact region 23 at, on, or coupled to bottom surface 29. Component contact region 23 may be coupled to a respective board contact region 93 of circuit board 90, which may be at, on, or coupled to top surface 91 of circuit board 90, for example.

Component contact region 23 and board contact region 93 may be directly coupled to one another.

Moreover, circuit board 90 may include one or more ground or common voltage contact regions 95. Each common voltage contact region 95 may, for example, be provided on top surface 91 of circuit board 90. As shown in FIGS. 4-7, for example, each common voltage contact region 95 may be electrically coupled to a ground or common voltage plane 97 of circuit board 90 through a respective via 96. It is to be understood that each component contact region 23, board contact region 93, and common voltage contact region 95 may have any of a variety of shapes, sizes, and locations relative to the remainder of the associated electronic component 20 or circuit board 90.

FIGS. 1-7 illustrate shield assembly 70 in various stages of assemblage. When fully assembled, shield assembly 70 may protect a circuitry region 25 of electronic device 10 from interference, and each circuitry region 25 may include one or more electronic components. For example, as shown in FIGS. 1-7, circuitry region 25 may include electronic component 20 protected by shield assembly 70. Shield assembly 70 may include a shield fence 30 and a shield lid 40. Shield fence 30 may be provided about the periphery of circuitry region 25 and may be coupled to circuit board 90. Shield lid 40 may be coupled to shield fence 30. Although FIGS. 1-7 only show one electronic component (i.e., component 20) included within circuitry region 25, in other embodiments, two or more electronic components may be included within the circuitry region protected by shield assembly 70.

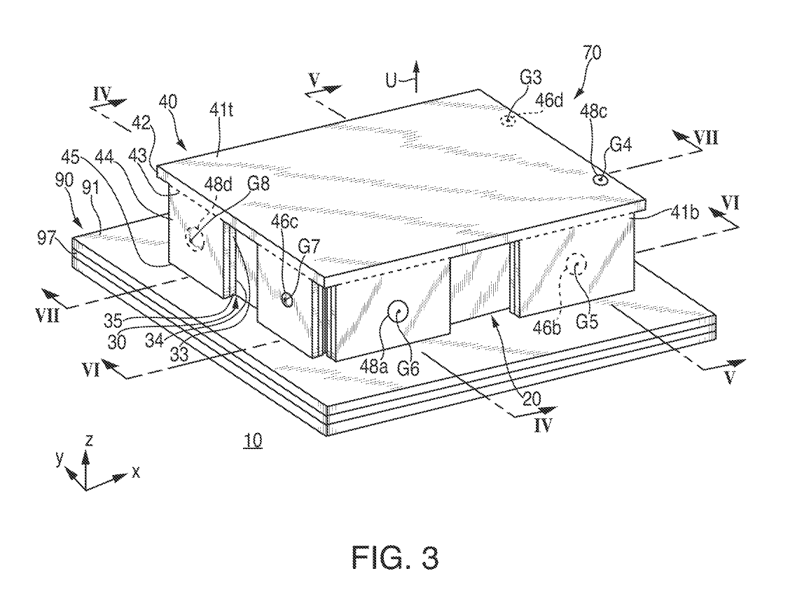

According to some embodiments, shield fence 30 may include a fence body 32 and a number of fence fingers 34. Each fence finger 34 may extend from a body fence finger portion 33 coupled to fence body 32, downwardly away from fence body 32, to a free-end fence finger portion 35. At least some free-end fence finger portions 35 of shield fence 30 may be coupled to top surface 91 of circuit board 90 about and/or adjacent to electronic component 20. According to some embodiments, shield lid 40 may include a lid body 42 and a number of lid fingers 44. Each lid finger 44 may extend from a body lid finger portion 43 coupled to lid body 42, downwardly away from lid body 42, to a free-end lid finger portion 45. When shield assembly 70 is fully assembled (see, e.g., FIGS. 3-7), portions of shield lid 40 may be electrically coupled to respective portions of shield fence 30 for forming an interference shield about circuitry region 25. For example, when shield assembly 70 is fully assembled, at least some lid fingers 44 of shield lid 40 may be electrically coupled to respective fence fingers 34. Additionally or alternatively, in some embodiments, when shield assembly 70 is fully assembled, at least a portion of lid body 42 may be electrically coupled to a portion of fence body 32.

As shown in FIGS. 1-7, fence body 32 of shield fence 30 of shield assembly 70 may include a top fence body surface 31t and a bottom fence body surface 31b. Fence body 32 may be any suitable shape. For example, as shown, fence body 32 may be rectangular with four sides. Shield fence 30 may also include any suitable number of fence fingers 34, and each fence finger 34 may have an inner fence finger surface 34i and an outer fence finger surface 34o. For example, as shown, shield fence 30 may include eight fence fingers 34 extending from fence body 32. Although shield fence 30 is shown to include two fence fingers 34 extending from each one of the four sides of fence body 32, shield fence 30 may include any suitable number of fence fingers 34, and different sides of fence body 32 may have different numbers of fence fingers 34 extending therefrom. In some embodiments, at least one side of fence body 32 may have no fence fingers 34 extending therefrom. Fence fingers 34 may be provided to extend from any suitable positions of fence body 32 such that fence fingers 34 may be provided about at least a portion of the periphery of circuitry region 25 and/or adjacent at least a portion of circuitry region 25 when free-end fence finger portions 35 are coupled to circuit board 90.

For example, in some embodiments, as shown, at least one fence finger 34 may extend substantially perpendicularly from fence body 32 (e.g., a fence finger 34 may extend in an X-Z plane or a Y-Z plane that may be perpendicular to fence body 32 that may reside in an X-Y plane). An inner surface 34i of at least one fence finger 34 may face an adjacent side of electronic component 20 of region 25 (e.g., a side of electronic component 20 extending between top surface 21 and bottom surface 23 of component 20).

Moreover, in some embodiments, as shown, at least a portion of fence body 32 may be parallel to circuit board 90 (e.g., at least a portion of top fence body surface 31t and/or at least a portion of bottom fence body surface 31b may be parallel to at least a portion of top surface 91 of circuit board 90).

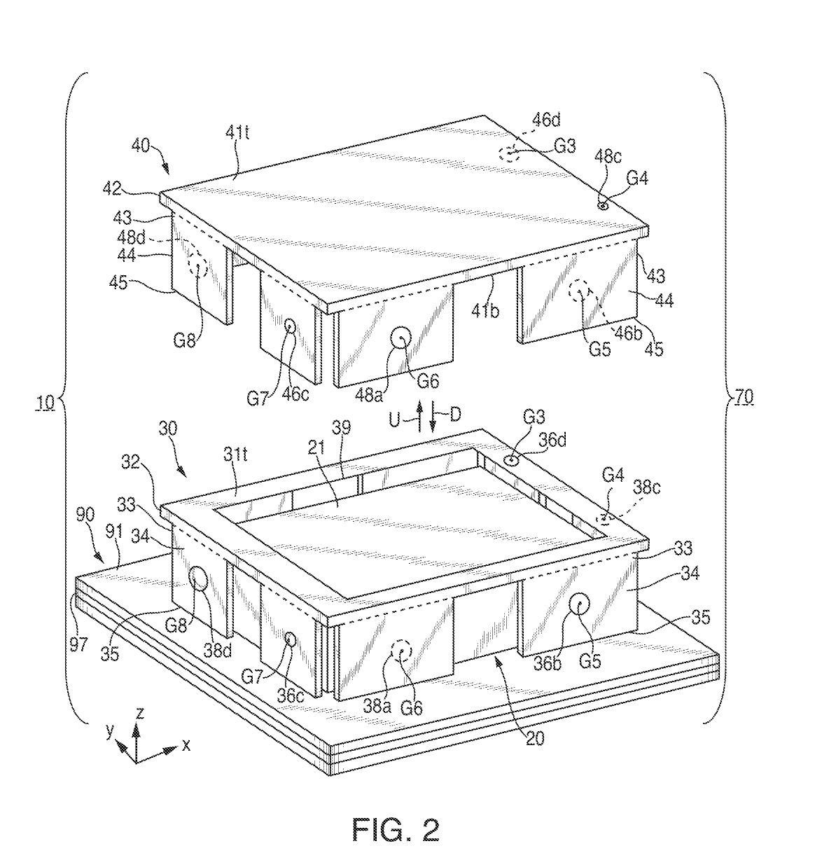

Shield fence 30 may also include at least one fence body opening 39 that may be provided through fence body 32 between top surface 31t and bottom surface 31b. For example, as shown in FIG. 2, when shield fence 30 is coupled to circuit board 90, electronic component 20 of circuitry region 25 may be accessible through opening 39 (e.g., component 20 may be passed through opening 39 and coupled to board 90 after shield fence 30 is coupled to board 90, or fence 30 may be coupled to board 20 after component 20 is coupled to board 90 and then an underfill (e.g., hardening epoxy material) may then be applied between component 20 and board 90 using needle applicators that may access the appropriate portions of component 20 through opening 39).

As also shown in FIGS. 1-7, lid body 42 of shield lid 40 of shield assembly 70 may include a top lid body surface 41t and a bottom lid body surface 41b. Lid body 42 may be any suitable shape. For example, as shown, lid body 42 may be rectangular with four sides. Shield lid 40 may also include any suitable number of lid fingers 44, and each lid finger 44 may have an inner lid finger surface 44i and an outer lid finger surface 44o. For example, as shown, shield lid 40 may include six lid fingers 44 extending from lid body 42. Although shield lid 40 is shown to include two lid fingers 44 extending from three of the four sides of lid body 42, shield lid 40 may include any suitable number of lid fingers 44, and different sides of lid body 42 may have different numbers of lid fingers 44 extending therefrom. In some embodiments, as shown, at least one side of lid body 42 may have no lid fingers 44 extending therefrom. Lid fingers 44 may be provided to extend from any suitable positions of lid body 42 such that lid fingers 44 may be provided about at least a portion of the periphery of circuitry region 25 when shield fence 30 is coupled to circuit board 90 and shield lid 40.

In some embodiments, as shown, at least one lid finger 44 may extend substantially perpendicularly from lid body 42 (e.g., a lid finger 44 may extend in an X-Z plane or a Y-Z plane that may be perpendicular to lid body 42 that may reside in an X-Y plane). An inner surface 44i of at least one lid finger 44 may extend adjacent to and face an outer surface 34o of a fence finger 34. Moreover, in some embodiments, as shown, at least a portion of lid body 42 may be parallel to circuit board 90 (e.g., at least a portion of top lid body surface 41t and/or at least a portion of bottom lid body surface 41b may be parallel to at least a portion of top surface 91 of circuit board 90).

Shield assembly 70 may be assembled about circuitry region 25 in various suitable ways. For example, in some embodiments, shield fence 30 may be coupled to circuit board 90 about circuitry region 25 (e.g., by lowering shield fence 30 in the direction of arrow D of FIG. 1 onto circuit board 90), and then shield lid 40 may be coupled to shield fence 30 (e.g., by lowering shield lid 40 in the direction of arrow D of FIG. 2 onto shield fence 30). In other embodiments, shield lid 40 may be coupled to shield fence 30, and then shield fence 30 may be coupled to circuit board 90 about circuitry region 25. Lid body 42 may be configured to cover at least a portion or the entirety of fence body opening 39 when lid 40 is coupled to fence 30 for forming shield assembly 70. For example, as shown in FIGS. 3-7, when assembly 70 is assembled, bottom surface 41b of lid body 42 may face top surface 31t of fence body 32 and lid body 42 may cover opening 39.

Shield fence 30 may be coupled to circuit board 90 by coupling at least one free-end fence finger portion 35 to top surface 91 of circuit board 90, for example, such that free-end fence finger portions 35 of shield fence 30 may circumscribe at least a portion of circuitry region 25 (e.g., at least a portion of bottom surface 29 of electronic component 20). Shield fence 30 may be electrically coupled to at least one common voltage contact region 95 of circuit board 90. For example, as shown in FIGS. 4-7, at least a portion of one free-end fence finger portion 35 of shield fence 30, or each free-end fence finger portion 35 of shield fence 30, may be disposed on top of and electrically coupled to a common voltage contact region 95 (e.g., via solder 94). However, in other embodiments, a portion of shield fence 30 may be electrically coupled to a common voltage contact region 95 in various other ways, such as via a wire (not shown). At least one free-end fence finger portion 35 of shield fence 30 may be fixedly attached to circuit board 90, such that shield assembly 70 may maintain its positional relationship with respect to circuitry region 25 for providing interference shielding. For example, solder 94 may not only electrically couple a free-end fence finger portion 35 to circuit board 90, but it may also fix fence shield 30 to circuit board 90. Alternatively, shield fence 30 may be electrically coupled to circuit board 90 and fixed to circuit board 90 using different techniques. For example, a first portion of shield fence 30 may be electrically coupled to a common voltage contact region 95 of circuit board 90 by a wire or by simply resting a first portion of shield fence 30 on top of a common voltage contact region 95, while a second portion of shield fence 30 may be fixedly attached to circuit board 90 by a screw, adhesive, or any other suitable securing technique.

Shield lid 40 may be coupled to shield fence 30 by interlocking at least one interlocking lid feature 46 of shield lid 40 with at least one respective interlocking fence feature 36 of shield fence 30 when shield assembly 70 is fully assembled. An interlocking fence feature 36 and an associated interlocking lid feature 46 may include any suitable elements that may interlock or otherwise interact with one another in any suitable manner for restricting the movement of shield lid 40 with respect to shield fence 30 in at least one direction or at least one degree of freedom when shield assembly 70 is fully assembled. Moreover, in some embodiments, the elements of an interlocking fence feature 36 and an associated interlocking lid feature 46 may also interlock or otherwise interact with one another to ensure or at least promote an interference fit or any suitable contact between one another. Such contact may electrically couple shield lid 40 to shield fence 30 for providing a ground point that may allow shield assembly 70 to properly shield electrical region 25 when shield assembly 70 is fully assembled. The elements of an interlocking fence feature 36 and an associated interlocking lid feature 46 may include any suitable elements that may appropriately interlock or otherwise interact with one another in any suitable manner, such as a protrusion/hole interaction, a flange/recess interaction, or any other suitable mechanical interaction.

For example, as shown in FIGS. 1-4, an interlocking lid feature 46 of shield lid 40 may include a dimple or protrusion 46a extending out away from an inner lid finger surface 44i of a lid finger 44, and an associated interlocking fence feature 36 of shield fence 30 may include a hole 36a extending through an outer fence finger surface 340 of a fence finger 34. When shield lid 40 is lowered over shield fence 30 in the direction of arrow D, at least a portion of inner lid finger surface 44i may align with at least a portion of outer fence finger surface 34o such that protrusion 46a of shield lid 40 may be configured to snap into or otherwise at least partially be retained within hole 36a of shield fence 30. Once shield lid 40 is lowered over shield fence 30 in the direction of arrow D far enough that protrusion 46a has snapped into or otherwise entered hole 36a, protrusion 46a may interact with a portion of fence finger 34 about hole 36a to prevent or severely limit the movement of shield lid 40 with respect to shield fence 30 in at least the Z-direction, and maybe also the X-direction and/or Y-direction. Moreover, protrusion 46a and hole 36a may be relatively sized to ensure or at least promote an interference fit or any suitable contact between protrusion 46a and a portion of fence finger 34 about hole 36a. Such contact between protrusion 46a and a portion of fence finger 34 about hole 36a may electrically couple shield lid 40 to shield fence 30, which may provide at least one ground point G1, and which may allow shield assembly 70 to properly shield electrical region 25.

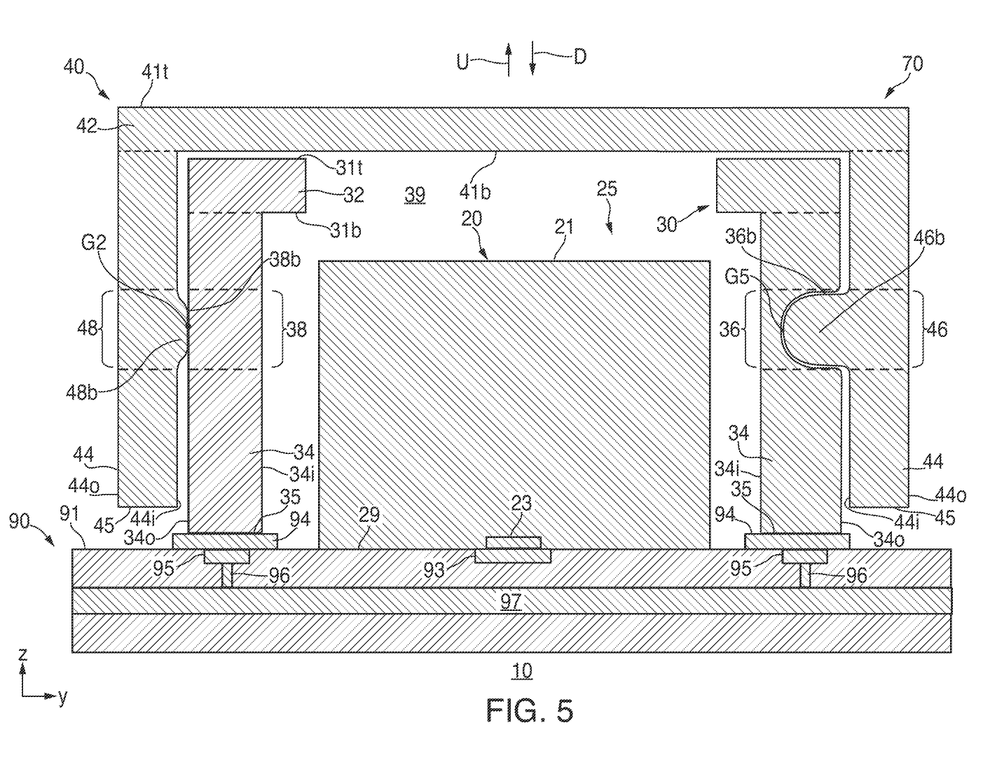

Additionally or alternatively, as shown in FIGS. 1-3 and 5, an interlocking lid feature 46 of shield lid 40 may include a dimple or protrusion 46b extending out away from an inner lid finger surface 44i of a lid finger 44, and an associated interlocking fence feature 36 of shield fence 30 may include a hole 36b extending through an outer fence finger surface 34o of a fence finger 34. In some embodiments, when shield lid 40 is lowered over shield fence 30 in the direction of arrow D, not only may protrusion 46a be configured to snap into hole 36a, but protrusion 46b may be configured to snap into hole 36b. In some embodiments, the interaction of protrusion 46b with hole 36b may be substantially similar to the interaction of protrusion 46a with hole 36a (e.g., the interaction of protrusion 46b with hole 36b may limit the movement of shield lid 40 with respect to shield fence 30 in at least the Z-direction and maybe also the X-direction and/or Y-direction, and the interaction of protrusion 46b with hole 36b may electrically couple shield lid 40 to shield fence 30 at a ground point G5). However, in some embodiments, while protrusion 46a may be formed on the inner lid finger surface 44i of a lid finger 44 by creating a respective indentation in the outer lid finger surface 44o of the same lid finger 44 (see, e.g., FIG. 4), protrusion 46b may be formed on the inner lid finger surface 44i of a lid finger 44 in any suitable manner that does not create a respective indentation in the outer lid finger surface 44o of the same lid finger 44 (see, e.g., FIG. 5). Moreover, in some embodiments, while hole 36a may be formed all the way through a fence finger 34 between its inner fence finger surface 34i and its outer fence finger surface 34o (see, e.g., FIG. 4), hole 36b may be formed only partially through a fence finger 34 from its outer fence finger surface 34o (see, e.g., FIG. 5).

Additionally or alternatively, as shown in FIGS. 1-3 and 6, an interlocking fence feature 36 of shield fence 30 may include a dimple or protrusion 36c extending out away from an outer fence finger surface 34o of a fence finger 34, and an associated interlocking lid feature 46 of shield lid 40 may include a hole 46c extending through an inner lid finger surface 44i of a lid finger 44. In some embodiments, when shield lid 40 is lowered over shield fence 30 in the direction of arrow D, not only may protrusion 46a be configured to snap into hole 36a, and not only may protrusion 46b be configured to snap into hole 36b, but protrusion 36c may be configured to snap into hole 46c. In some embodiments, the interaction of protrusion 36c with hole 46c may be substantially similar to the interaction of protrusion 46a with hole 36a and/or protrusion 46b with hole 36b (e.g., the interaction of protrusion 36c with hole 46c may limit the movement of shield lid 40 with respect to shield fence 30 in at least the Z-direction, and the interaction of protrusion 36c with hole 46c may electrically couple shield lid 40 to shield fence 30 at a ground point G7). However, rather than also possibly limiting the movement of shield lid 40 with respect to shield fence 30 in the X-direction like protrusion 46a and hole 36a, protrusion 36c and hole 46c may be configured to limit the movement of shield lid 40 with respect to shield fence 30 in the Y-direction (e.g., because protrusion 36c and hole 46c may be provided in fingers extending along a side of shield assembly 70 that is perpendicular to the side of shield assembly 70 along which the fingers including protrusion 46a and hole 36a extend).

Additionally or alternatively, as shown in FIGS. 1-3 and 7, an interlocking lid feature 46 of shield lid 40 may include a dimple or protrusion 46d extending out away from bottom lid body surface 41b of lid body 42, and an associated interlocking fence feature 36 of shield fence 30 may include a hole 36d extending through top fence body surface 31t of fence body 32. In some embodiments, when shield lid 40 is lowered over shield fence 30 in the direction of arrow D, not only may protrusion 46a be configured to snap into hole 36a, not only may protrusion 46b be configured to snap into hole 36b, and not only may protrusion 36c be configured to snap into hole 46c, but protrusion 46d may be configured to at least partially enter or otherwise interact with hole 36d. In some embodiments, the interaction of protrusion 46d with hole 36d may be substantially similar to the interaction of protrusion 46a with hole 36a (e.g., the interaction of protrusion 46d with hole 36d may limit the movement of shield lid 40 with respect to shield fence 30 in at least one direction, and the interaction of protrusion 46d with hole 36d may electrically couple shield lid 40 to shield fence 30 at a ground point G3). However, because protrusion 46d is provided on lid body 42 rather than on a lid finger 44, and because hole 36d is provided on fence body 32 rather than on a fence finger 34, protrusion 46d and hole 36d may limit the movement of shield lid 40 with respect to shield fence 30 in at least one of the X-direction and the Y-direction, rather than the Z-direction.

In addition to or as an alternative to interlocking one or more interlocking fence features 36 with one or more interlocking lid features 46, shield lid 40 may additionally or alternatively be coupled to shield fence 30 by ensuring contact between at least one contacting lid feature 48 of shield lid 40 with at least one respective contacting fence feature 38 of shield fence 30 when shield assembly 70 is fully assembled. A contacting fence feature 38 and an associated contacting lid feature 48 may include any suitable elements that may ensure contact between features 38 and 48 in any suitable manner for electrically coupling shield lid 40 to shield fence 30 for providing a ground point that may allow shield assembly 70 to properly shield electrical region 25 when shield assembly 70 is fully assembled. The elements of a contacting fence feature 38 and an associated contacting lid feature 48 may include any suitable elements that may appropriately ensure contact between features 38 and 48 in any suitable manner.

For example, as shown in FIGS. 1-4, a contacting lid feature 48 of shield lid 40 may include a dimple or protrusion 48a extending out away from an inner lid finger surface 44i of a lid finger 44, and an associated contacting fence feature 38 of shield fence 30 may include a flat or substantially flat surface portion 38a along an outer fence finger surface 34o of a fence finger 34. When shield lid 40 is lowered over shield fence 30 in the direction of arrow D, at least a portion of inner lid finger surface 44i may align with at least a portion of outer fence finger surface 34o such that protrusion 48a of shield lid 40 may be configured to initiate and maintain contact with surface portion 38a of shield fence 30. Once shield lid 40 is lowered over shield fence 30 in the direction of arrow D far enough that protrusion 48a has contacted surface portion 38a, protrusion 48a may be configured to (e.g., biased or sized to) interact with surface portion 38a of fence finger 34 to ensure and maintain suitable contact between protrusion 48a and surface portion 38a of fence finger 34 for electrically coupling shield lid 40 to shield fence 30, which may provide a ground point G6 at the point of contact that may allow shield assembly 70 to properly shield electrical region 25.

Additionally or alternatively, as shown in FIGS. 1-3 and 5, a contacting lid feature 48 of shield lid 40 may include a dimple or protrusion 48b extending out away from an inner lid finger surface 44i of a lid finger 44, and an associated contacting fence feature 38 of shield fence 30 may include a flat or substantially flat surface portion 38b along an outer fence finger surface 340 of a fence finger 34. In some embodiments, when shield lid 40 is lowered over shield fence 30 in the direction of arrow D, not only may protrusion 48a be configured to maintain contact with surface portion 38a, but protrusion 48b may be configured to maintain contact with surface portion 38b. In some embodiments, the interaction of protrusion 48b with surface portion 38b may be substantially similar to the interaction of protrusion 48a with surface portion 38a (e.g., the interaction of protrusion 48b with surface portion 38b may consistently electrically couple shield lid 40 to shield fence 30 at a ground point G2). However, in some embodiments, while protrusion 48a may be formed on the inner lid finger surface 44i of a lid finger 44 by creating a respective indentation in the outer lid finger surface 44o of the same lid finger 44 (see, e.g., FIG. 4), protrusion 48b may be formed on the inner lid finger surface 44i of a lid finger 44 in any suitable manner that does not create a respective indentation in the outer lid finger surface 44o of the same lid finger 44 (see, e.g., FIG. 5).

Additionally or alternatively, as shown in FIGS. 1-3 and 6, a contacting lid feature 48 of shield lid 40 may include a dimple or protrusion 48c extending out away from bottom lid body surface 41b of lid body 42, and an associated contacting fence feature 38 of shield fence 30 may include a flat or substantially flat surface portion 38c along top fence body surface 31t of fence body 32. In some embodiments, when shield lid 40 is lowered over shield fence 30 in the direction of arrow D, not only may protrusion 48a be configured to contact surface portion 38a, and not only may protrusion 48b be configured to contact surface portion 38b, but protrusion 48c may be configured to contact surface portion 38c. In some embodiments, the interaction of protrusion 48c with surface portion 38c may be substantially similar to the interaction of protrusion 48a with surface portion 38a (e.g., the interaction of protrusion 48c with surface portion 38c may consistently electrically couple shield lid 40 to shield fence 30 at a ground point G4). However, because protrusion 48c is provided on lid body 42 rather than on a lid finger 44, and because surface portion 38c is provided on fence body 32 rather than on a fence finger 34, protrusion 48c and surface portion 38c may ensure contact between lid body 42 and fence body 32 (e.g., in the X-Y plane extending above circuitry region 25 and between lid body 42 and fence body 32), rather than ensure contact between a lid finger 44 and a fence finger 34 (e.g., in an X-Z plane extending along a side of circuitry region 25 and between lid finger 44 and fence finger 34).

Additionally or alternatively, as shown in FIGS. 1-3 and 7, a contacting fence feature 38 of shield fence 30 may include a dimple or protrusion 38d extending out away from an outer fence finger surface 34o of a fence finger 34, and an associated contacting lid feature 48 of shield lid 40 may include a flat or substantially flat surface portion 48d along an inner lid finger surface 44i of a lid finger 44. In some embodiments, when shield lid 40 is lowered over shield fence 30 in the direction of arrow D, not only may protrusion 48a be configured to contact surface portion 38a, and not only may protrusion 48b be configured to contact surface portion 38b, and not only may protrusion 48c be configured to contact surface portion 38c, but protrusion 38d be configured to contact surface portion 48d. In some embodiments, the interaction of protrusion 38d with surface portion 48d may be substantially similar to the interaction of protrusion 48a with surface portion 38a and/or protrusion 48b with surface portion 38b (e.g., the interaction of protrusion 38d with surface portion 48d may ensure contact between a lid finger 44 and a fence finger 34 at a ground point G8). However, rather than also ensuring contact between a lid finger 44 and a fence finger 34 in an X-Z plane extending along a side of circuitry region 25 and between lid finger 44 and fence finger 34, protrusion 38d and surface portion 48d may ensure contact between a lid finger 44 and a fence finger 34 in a Y-Z plane extending along a side of circuitry region 25 and between lid finger 44 and fence finger 34 (e.g., because protrusion 38d and surface portion 48d may be provided in fingers extending along a side of shield assembly 70 that is perpendicular to the side of shield assembly 70 along which the fingers including protrusion 48a and surface portion 38a extend).

In some embodiments, when shield fence 30 is coupled to circuit board 90, as shown in FIGS. 2-7, shield fence 30 may be fixedly attached to circuit board 90 such that a user (e.g., a manufacturer of device 10) may not unattach shield fence 30 from circuit board 90 (e.g., in the direction of arrow U of

FIG. 2) without a tool or without damaging the element or elements that fixedly attach fence 30 to board 90. For example, if a screw (not shown) fixedly attaches shield fence 30 to circuit board 90, then a user may need a screwdriver to unattach shield fence 30 from circuit board 90. As another example, if solder 94 fixedly attaches shield fence 30 to circuit board 90, as shown in FIGS. 2-7, then a user may need to irreversibly break solder 94 to unattach shield fence 30 from circuit board 90 (e.g., new solder 94 may be needed to fixedly reattach shield fence 30 to circuit board 90).

However, when shield fence 30 is coupled to shield lid 40, as shown in FIGS. 3-7, shield lid 40 may be removably coupled to shield fence 30 such that a user (e.g., a manufacturer of device 10) may uncouple shield lid 40 from shield fence 30 (e.g., in the direction of arrow U of FIG. 2) without a tool or without damaging or otherwise impairing the element or elements that removably couple fence 30 to lid 40. For example, the interaction between each interlocking lid feature 46 of shield lid 40 and its associated interlocking fence feature 36 of shield fence 30 may not prevent a user from uncoupling lid 40 from fence 30 and/or may not irreversibly break when lid 40 is uncoupled from fence 30. That is, at least one interlocking lid feature 46 of shield lid 40 and its associated interlocking fence feature 36 of shield fence 30 may not be impaired when lid 40 is uncoupled from fence 30. Similarly, the interaction between each contacting lid feature 48 of shield lid 40 and its associated contacting fence feature 38 of shield fence 30 may not prevent a user from uncoupling lid 40 from fence 30 and/or may not irreversibly break when lid 40 is uncoupled from fence 30. That is, at least one contacting lid feature 48 of shield lid 40 and its associated contacting fence feature 38 of shield fence 30 may not be impaired when lid 40 is uncoupled from fence 30. Therefore, even after shield assembly 70 is fully assembled, a user may uncouple shield lid 40 from shield fence 30 (e.g., to access electronic region 25 through fence body opening 39 of fence body 32) without breaking or impairing one or more features 36, 38, 46, or 48.

When configured to limit the movement between lid 40 and shield 30 in at least one direction, the interaction between an interlocking lid feature 46 of lid 40 and its associated interlocking fence feature 36 of fence 30 may provide more resistance to a user uncoupling lid 40 from fence 30 than may the resistance that may be provided by the interaction between a contacting lid feature 48 of lid 40 and its associated contacting fence feature 38 of fence 30, which may not be configured to limit the movement between lid 40 and shield 30. Therefore, in some embodiments, sets of contacting features 38/48 may be interspersed amongst sets of interlocking features 36/46 about shield assembly 70 so that the resistance to uncoupling lid 40 from shield 30 that may be provided by these features may be evenly distributed about shield assembly 70 and circuitry region 25. For example, as shown in

FIGS. 1-7, the feature set of hole 36a/protrusion 46a may be positioned about shield assembly 70 between the feature set of surface 38b/protrusion 48b and the feature set of protrusion 38d/surface 48d, while the feature set of hole 36b/protrusion 46b may be positioned about shield assembly 70 between the feature set of surface 38a/protrusion 48a and the feature set of surface 38c/protrusion 48c, and while the feature set of protrusion 36c/hole 46c may be positioned about shield assembly 70 between the feature set of surface 38a/protrusion 48a and the feature set of protrusion 38d/surface 48d, and while the feature set of hole 36d/protrusion 46d may be positioned about shield assembly 70 between the feature set of surface 38b/protrusion 48b and the feature set of surface 38c/protrusion 48c.

Every ground point G1-G8 of shield assembly 70 may together define a closed loop of ground points along/about lid 40 (see, e.g., closed loop CL of FIG. 1, which may extend from point G1 to adjacent point G2 to adjacent point G3 to adjacent point G4 to adjacent point G5 to adjacent point G6 to adjacent point G7 to adjacent point G8 to adjacent point G1).

In some embodiments, in order for shield assembly 70 to provide appropriate interference shielding, each particular ground point of the closed loop may not be positioned more than a maximum threshold distance away from each of the two ground points adjacent to that particular ground point in the loop. For example, in some embodiments, any two adjacent ground points in closed loop CL of ground points G1-G8 provided by shield assembly 70 must be positioned within a particular threshold distance of one another (e.g., 3.0 millimeters).

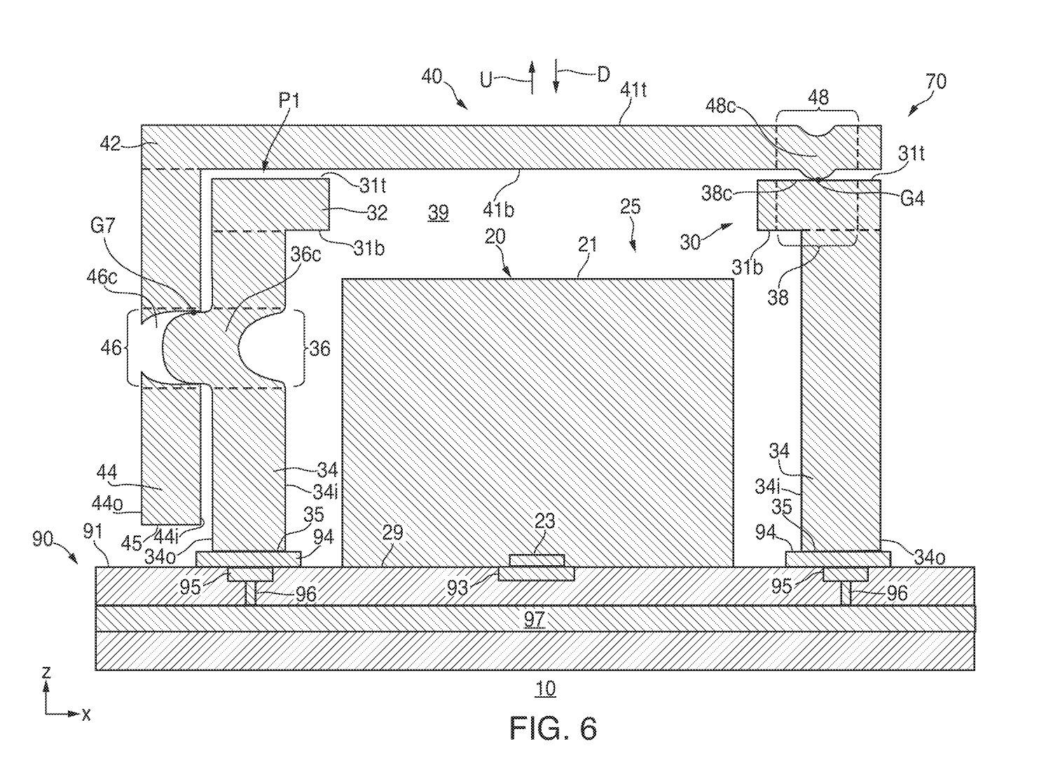

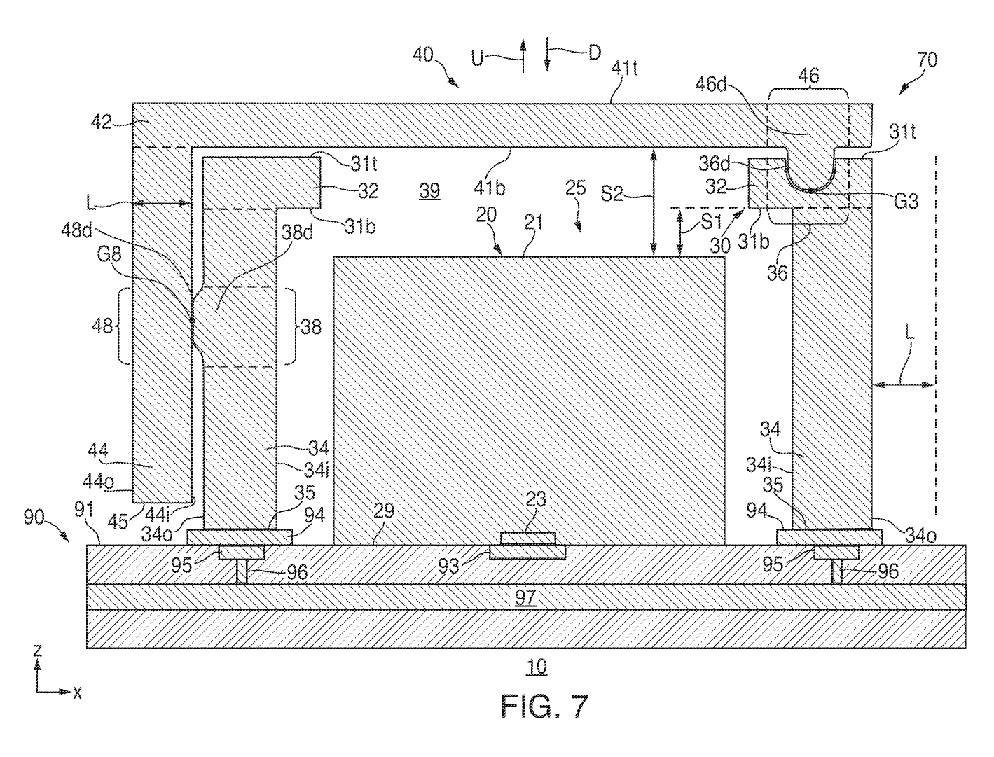

However, as shown in FIGS. 6 and 7, for example, shield lid 40 may not include a lid finger 44 extending downwardly from at least one side of lid body 42 (e.g., adjacent the outer surface 34o of the fence finger 34 shown on the right-hand side of each one of FIGS. 6 and 7). Although this may reduce the length of shield assembly 70 along the X-direction (e.g., by a length L, which may be at least equal to a thickness of a lid finger 44, as shown in FIG. 7), the lack of a lid finger 44 extending adjacent either of the fence fingers 34 on that side of shield assembly 70 may deprive those fence fingers 34 of the ability to interact with (e.g., form a ground point with) a portion of shield lid 40. Therefore, without providing the two ground points between lid body 42 and fence body 32 (e.g., ground point G3 provided by the feature set of hole 36d/protrusion 46d and ground point G4 provided by the feature set of surface 38c/protrusion 48c), the distance between ground point G2 provided by the feature set of surface 38b/protrusion 48b and ground point G5 provided by the feature set of hole 36b/protrusion 46b may have exceeded the maximum distance threshold between two adjacent ground points in a closed loop of ground points of shield assembly 70.

Shield fence 30 and shield lid 40 may each be formed from any suitable material or groups of materials that may be at least partially conductive for shielding circuitry region 25. For example, each one of shield fence 30 and shield lid 40 may be formed from any suitable metal, such as aluminum. In some embodiments, each one of fence 30 and lid 40 may be formed from a single piece of solid material. The single piece of material may, for example, be a piece of flat stock (e.g., sheet metal). Each one of fence 30 and lid 40 may be formed by one or more various suitable processes including, but not limited to, a machining process, an extrusion process, a forging process, and combinations thereof. For example, in some embodiments, each one of fence 30 and lid 40 may be at least partially formed by a forging process, which may include a process of working a hot or cold material, such as metal, to a desired shape by impact or pressure from hammers, presses, or forging machines. For example, forging may be used to help form the edges of fence body 32, the edges of lid body 42, the intersection of fence body 32 with one or more fence fingers 34, and/or the intersection of lid body 42 with one or more lid fingers 44.

Additionally or alternatively, the process of forming each one of fence 30 and lid 40 may include drawing, and further deep drawing. Drawing may refer to forming sheet metal into shapes, such as cylindrical or box shaped parts, by using a punch that may press the sheet metal into a die cavity. Drawing may also refer to placing a flat blank over a shaped punch to draw the flat material over a die, thereby creating a formed shape. In some embodiments, one or more drawing techniques may be used to form the general shape of shield fence 30 and/or shield lid 40, and thereafter forging may be used to adjust the thickness of the material at specific locations around the shaped part (e.g., forging can be used to create sharp edges at locations where drawing may have created edges with a radius).

One or more machining processes may further be applied to clean up one or more surfaces of shield fence 30 and/or shield lid 40 after other processes have been implemented. For example, machining may be used to clean up forged surfaces. Forging may be used to create coarse sharp corners and machining may be used to create fine sharp corners. As another example, forging may be used to over mold corners or edges of shield fence 30 and/or shield lid 40 so that there may be enough material to machine. Machining may also be used to add features on shield fence 30 and/or shield lid 40. For example, one or more fence body openings 39 may be machined into or through fence body 32. Additionally or alternatively, one or more of holes 36a, 46b, 46c, and 36d may be machined into or through fence 30 or lid 40. Additionally or alternatively, one or more of protrusions 46a, 48a, 46b, 48b, 36c, 48c, 38d, and 46d may be forged, machined, drawn, or otherwise formed into or through fence 30 or lid 40. Moreover, spacings 37 provided between adjacent fence fingers 34 and/or spacings 47 provided between adjacent lid fingers 44 may be machined, drawn, or otherwise formed into or through fence 30 or lid 40. Moreover, one or more other features of assembly 70, such as screw holes, posts, standoffs, bosses, recesses, and the like, may be created on or through surfaces of assembly 70. Additionally or alternatively, other processes may be utilized for forming shield fence 30 and/or shield lid 40, including, for example, punching, stamping, polishing, applying surface finishes (e.g., sand blasting, anodizing, etc.), ironing, extruding, cutting, molding, and the like.

Although each lid finger 44 of lid 40 is shown to include only a single interlocking lid feature 46 or a single contacting lid feature 48, each lid finger 44 may be provided with two or more of one or both such features. Similarly, although each fence finger 34 of fence 30 is shown to include only a single interlocking fence feature 36 or a single contacting fence feature 38, each fence finger 34 may be provided with two or more of one or both such features, and each one of such features my interact with an associated feature on an associated lid finger 44. For example, a particular fence finger may include both an interlocking fence feature 36 and a contacting fence feature 38, while an associated lid finger may include both an associated interlocking lid feature 46 and an associated contacting lid feature 48.

Although lid body 42 is only shown to electrically couple with fence body 32 at ground points G3 and G4 positioned above fence fingers 34 that do not share a ground point with a lid finger 44, lid body 42 and fence body 32 may share a ground point at any other suitable position (e.g., at a point P1 of FIG. 6 that may be positioned above a fence finger 34 that shares ground point G7 with a lid finger 44). Moreover, in some embodiments, rather than providing a fence finger 34 that does not share a ground point with any lid finger 44 (e.g., the fence finger 34 on the right-side of FIG. 6), shield assembly 70 may include at least one lid finger 44 that does not share a ground point with any fence finger 34. Moreover, rather than a lid finger 44 extending about fence 30 such that an inner surface 44i of the lid finger 44 may face an outer surface 34o of a fence finger 34 for sharing a ground point between the inner surface 44i and the outer surface 34o (e.g., as shown in FIGS. 1-7), one, some, or all of the lid fingers 44 of lid 40 may be configured to extend through an opening 39 of fence 30 such that an outer surface 44o of such a lid finger 44 may face an inner surface 34i of a fence finger 34 (e.g., for sharing a ground point between the outer surface 44o and the inner surface 34i).

Although shield assembly 70 of FIGS. 1-7 is shown to be configured such that bottom surface 31b of shield fence 30 may be positioned above top surface 21 of circuit component 20 by a spacing S1 when assembly 70 is fully assembled (see, e.g., FIG. 7), it is to be understood that, in some embodiments, top surface 21 of circuit component 20 may actually extend above fence bottom surface 31b, and even above fence top surface 31t (e.g., through fence opening 39). However, shield assembly 70 may always be configured such that bottom surface 41b of shield lid 40 is positioned above top surface 21 of circuit component 20 by a spacing S2 when assembly 70 is fully assembled (see, e.g., FIG. 7), for example, such that lid 40 may not contact component 20 and short any circuitry of component 20.

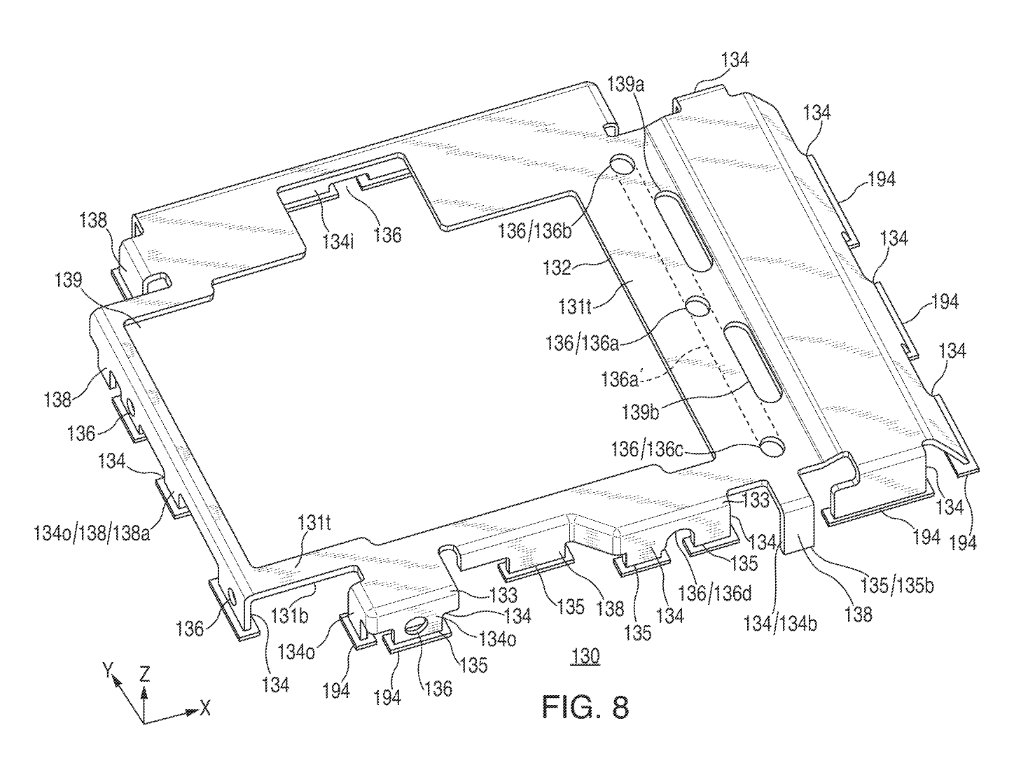

As shown in FIGS. 8-12A, for example, another shield assembly 170 may be provided to shield other components of electronic device 10. Shield assembly 170 may include a shield fence 130 and a shield lid 140 that may be assembled with a portion of circuit board 90 for shielding a circuitry region 125, which may include electronic components 120a, 120b, 120c, and 120d. Each one of electronic components 120a-120d of circuitry region 125 may be mounted or otherwise coupled to top surface 91 of circuit board 90 similarly to electronic component 20 of circuitry region 25.

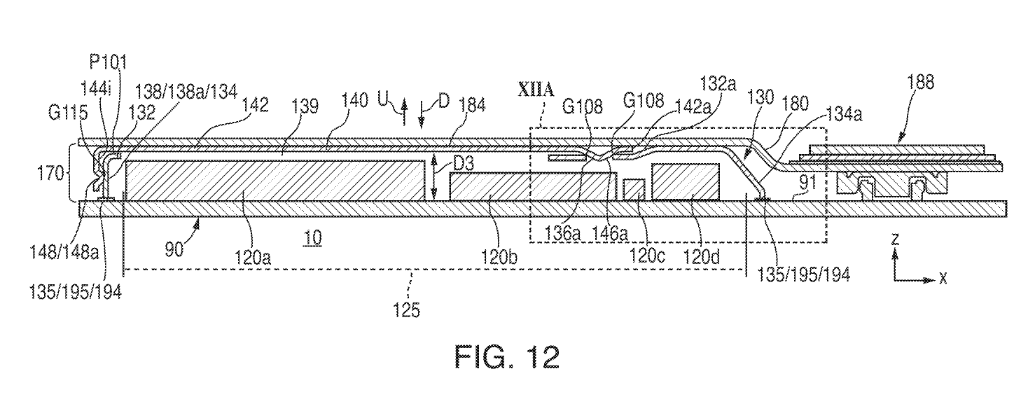

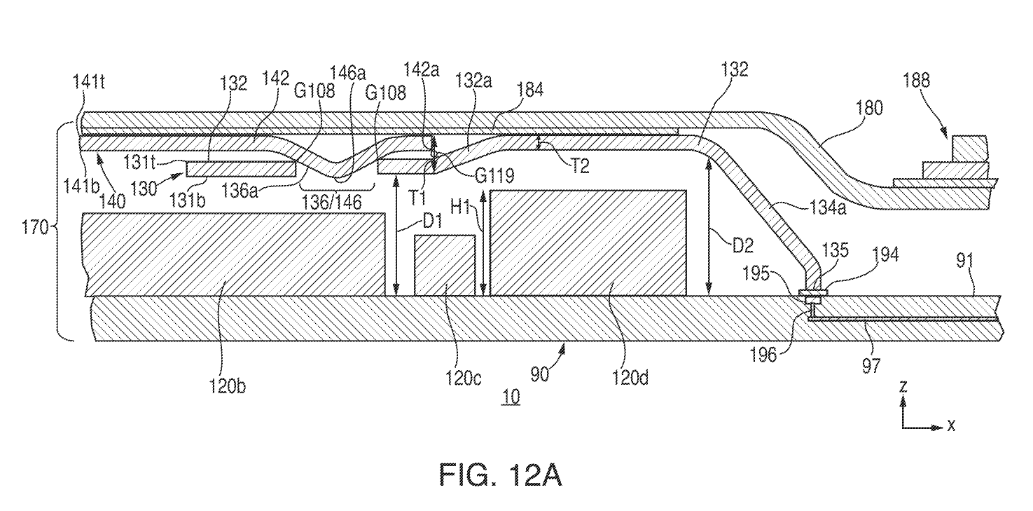

Although not shown, each one of electronic components 120a-120d may include at least one terminal or bond pad or other component contact region that may be coupled to circuitry (not shown) of the electronic component and that may be electrically coupled to a respective terminal, bond pad, or other type of board contact region of circuit board 90 (e.g., as described above with respect to regions 23 and 93 of FIGS. 1-7). Such board contact regions of circuit board 90 may also be coupled to one or more signal planes, vias, or other circuitry (not shown) of circuit board 90 (e.g., a ground or common voltage plane 97 of circuit board 90, as described above with respect to assembly 70). Moreover, as shown in FIGS. 12 and 12A, circuit board 90 may include one or more ground or common voltage contact regions 195. Like regions 95 described above with respect to FIGS. 1-7, each common voltage contact region 195 may, for example, be provided on top surface 91 of circuit board 90 and/or may be electrically coupled ground or common voltage plane 97 of circuit board 90 through a respective via 196.

FIGS. 8-12A illustrate shield assembly 170 in various stages of assemblage. When fully assembled, shield assembly 170 may protect circuitry region 125 of electronic device 10 from interference. Shield assembly 170 may include shield fence 130 and shield lid 140. Shield fence 130 may be substantially similar to shield fence 30 and may be provided about the periphery of circuitry region 125 and may be coupled to circuit board 90. Shield lid 140 may be substantially similar to shield lid 40 and may be coupled to shield fence 130.

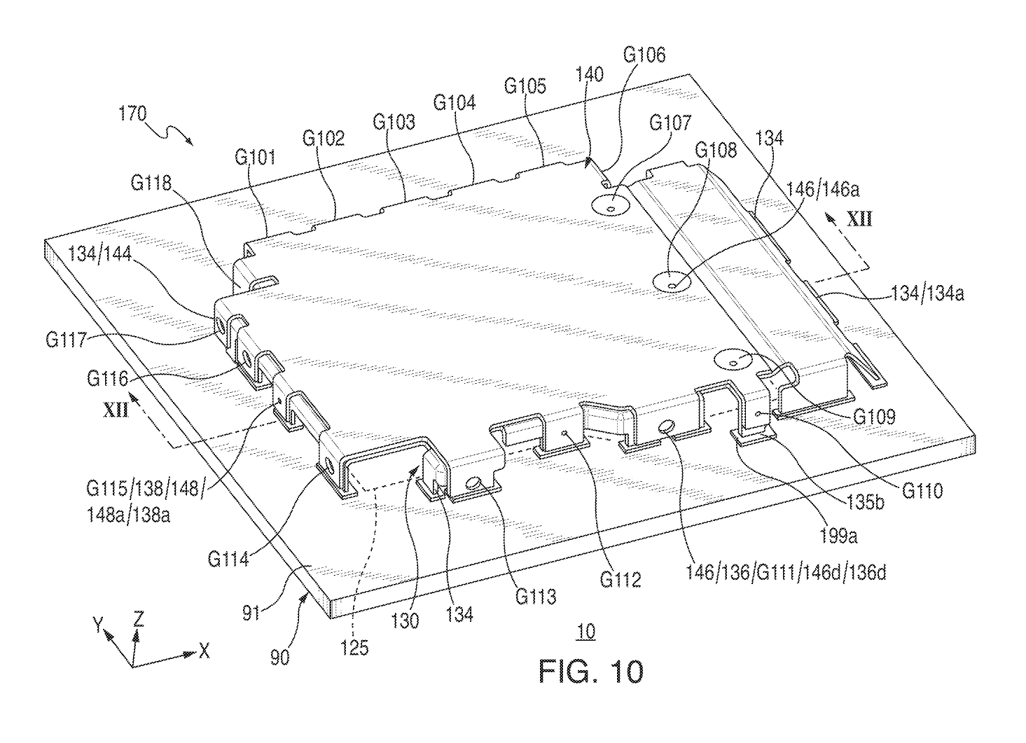

According to some embodiments, shield fence 130 may include a fence body 132 and a number of fence fingers 134. Each fence finger 134 may extend from a body fence finger portion 133 coupled to fence body 132, downwardly away from fence body 132, to a free-end fence finger portion 135. At least some free-end fence finger portions 135 of shield fence 130 may be coupled to top surface 91 of circuit board 90 about electronic components 120a-120d of circuitry region 125. According to some embodiments, shield lid 140 may include a lid body 142 and a number of lid fingers 144. Each lid finger 144 may extend from a body lid finger portion 143 coupled to lid body 142, downwardly away from lid body 142, to a free-end lid finger portion 145. When shield assembly 170 is fully assembled (see, e.g., FIGS. 10-12A), portions of shield lid 140 may be electrically coupled to respective portions of shield fence 130 for forming an interference shield about circuitry region 125. For example, when shield assembly 170 is fully assembled, at least some lid fingers 144 of shield lid 140 may be electrically coupled to respective fence fingers 134. Additionally or alternatively, in some embodiments, when shield assembly 170 is fully assembled, at least a portion of lid body 142 may be electrically coupled to a portion of fence body 132.

As shown in FIGS. 8 and 10-12A, fence body 132 of shield fence 130 of shield assembly 170 may include a top fence body surface 131t and a bottom fence body surface 131b. Fence body 132 may be any suitable shape. For example, as shown, unlike fence body 32, which may be substantially rectangular, fence body 132 may be irregularly shaped (e.g., to match any design constraints of circuitry region 125, components 120a-120d, or device 10). Shield fence 130 may also include any suitable number of fence fingers 134, and each fence finger 134 may have an inner fence finger surface 134i and an outer fence finger surface 134o. For example, as shown, shield fence 130 may include twenty-two fence fingers 134 extending from fence body 132. At least one free-end portion 135 of at least one fence finger 134 (e.g., free-end portion 135b of fence finger 134b) may not be coupled to board 90 via solder, but may instead be positioned within a groove or hole 199a made through top surface 91 of board 90 (e.g., to properly physically align fence 130 with top surface 91 of board 90). Shield fence 130 may include any suitable number of fence fingers 134, and different sides of fence body 132 may have different numbers of fence fingers 134 extending therefrom. In some embodiments, at least one side of fence body 132 may have no fence fingers 134 extending therefrom. Fence fingers 134 may be provided to extend from any suitable positions of fence body 132 such that fence fingers 134 may be provided about at least a portion of the periphery of circuitry region 125 when free-end fence finger portions 135 are coupled to circuit board 90.

Moreover, shield fence 130 may include at least one fence body opening 139 that may be provided through fence body 132 between top surface 131t and bottom surface 131b. For example, as shown in FIGS. 12 and 12A, when shield fence 130 is coupled to circuit board 90, at least one electronic component of circuitry region 125 may be accessible through opening 139 or opening 139a or opening 139b (e.g., component 120a may be passed through opening 139 and coupled to board 90 after shield fence 130 is coupled to board 90 or underfill may be applied between a component and board 90 through opening 139a or opening 139b).

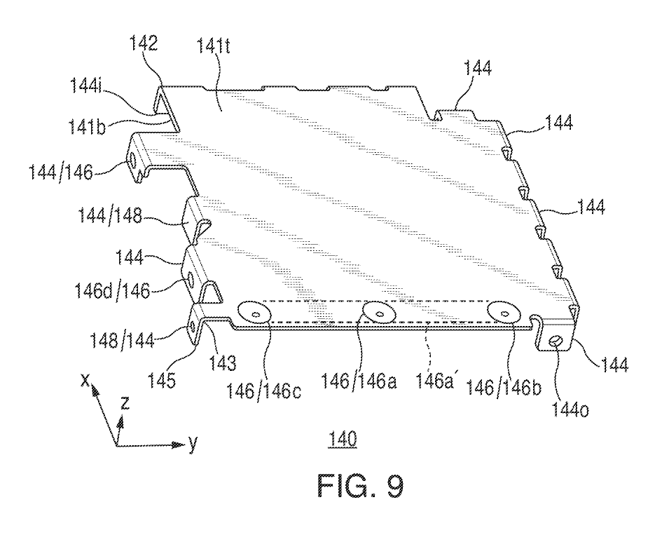

As also shown in FIGS. 9-12A, lid body 142 of shield lid 140 of shield assembly 170 may include a top lid body surface 141t and a bottom lid body surface 141b. Lid body 142 may be any suitable shape. For example, as shown, unlike lid body 42, which may be substantially rectangular, lid body 142 may be irregularly shaped (e.g., to match any design constraints of circuitry region 125, components 120a-120d, fence body 132, or device 10). Shield lid 140 may also include any suitable number of lid fingers 144, and each lid finger 144 may have an inner lid finger surface 144i and an outer lid finger surface 144o. For example, as shown, shield lid 140 may include fifteen lid fingers 144 extending from lid body 142. Shield lid 140 may include any suitable number of lid fingers 144, and different sides of lid body 142 may have different numbers of lid fingers 144 extending therefrom. In some embodiments, at least one side of lid body 142 may have no lid fingers 144 extending therefrom. Lid fingers 144 may be provided to extend from any suitable positions of lid body 142 such that lid fingers 144 may be provided about at least a portion of the periphery of circuitry region 125 when shield fence 130 is coupled to circuit board 90 and shield lid 140.

Shield assembly 170 may be assembled about circuitry region 125 in various suitable ways. For example, in some embodiments, shield fence 130 may be coupled to circuit board 90 about circuitry region 125 (e.g., by lowering shield fence 130 in the direction of arrow D of FIG. 12 onto circuit board 90), and then shield lid 140 may be coupled to shield fence 130 (e.g., by lowering shield lid 140 in the direction of arrow D of FIG. 12 onto shield fence 130). In other embodiments, shield lid 140 may be coupled to shield fence 130, and then shield fence 130 may be coupled to circuit board 90 about circuitry region 125.

Shield fence 130 may be coupled to circuitry region 90 by coupling at least one free-end fence finger portion 135 to top surface 91 of circuit board 90, for example, such that free-end fence finger portions 135 of shield fence 130 may circumscribe at least a portion of circuitry region 125. Shield fence 130 may be electrically coupled to at least one common voltage contact region 195 of circuit board 90.

For example, as shown in FIGS. 12 and 12A, at least a portion of one free-end fence finger portion 135 of shield fence 130 may be disposed on top of and electrically coupled to a common voltage contact region 195 (e.g., via solder 194). However, in other embodiments, a portion of shield fence 130 may be electrically coupled to a common voltage contact region 195 in various other ways, such as via a wire (not shown). As described above with respect to shield fence 30 of assembly 70, at least one free-end fence finger portion 135 of shield fence 130 may be fixedly attached to circuit board 90, such that shield assembly 170 may maintain its positional relationship with respect to circuitry region 125 for providing interference shielding. For example, solder 194 may not only electrically couple a free-end fence finger portion 135 to circuit board 90, but it may also fix fence shield 130 to circuit board 90. Alternatively, shield fence 130 may be electrically coupled to circuit board 90 and fixed to circuit board 90 using different techniques. For example, a first portion of shield fence 130 may be electrically coupled to a common voltage contact region 195 of circuit board 90 by a wire or by simply resting on top of region 195, while a second portion of shield fence 130 may be fixedly attached to circuit board 90 by a screw, adhesive, or any other suitable securing technique.

Shield lid 140 may be coupled to shield fence 130 by interlocking at least one interlocking lid feature 146 of shield lid 140 with at least one respective interlocking fence feature 136 of shield fence 130 when shield assembly 170 is fully assembled. An interlocking fence feature 136 and an associated interlocking lid feature 146 may include any suitable elements that may interlock or otherwise interact with one another in any suitable manner for restricting the movement of shield lid 140 with respect to shield fence 130 in at least one direction or at least one degree of freedom when shield assembly 170 is fully assembled. Moreover, in some embodiments, the elements of an interlocking fence feature 136 and an associated interlocking lid feature 146 may also interlock or otherwise interact with one another to ensure or at least promote an interference fit or any suitable contact between one another. Such contact may electrically couple shield lid 140 to shield fence 130 for providing a ground point that may allow shield assembly 170 to properly shield electrical region 125 when shield assembly 170 is fully assembled. The elements of an interlocking fence feature 136 and an associated interlocking lid feature 146 may include any suitable elements that may appropriately interlock or otherwise interact with one another in any suitable manner, such as a protrusion/hole interaction, a flange/recess interaction, or any other suitable mechanical interaction, as described above with respect to features 36/46.

For example, as shown in FIGS. 9-12A, an interlocking lid feature 146 of shield lid 140 may include a dimple or protrusion 146a extending out away from bottom lid body surface 141b of lid body 142, and an associated interlocking fence feature 136 of shield fence 130 may include a hole 136a extending at least partially through fence body 132. When shield lid 140 is lowered over shield fence 130 in the direction of arrow D, at least a portion of bottom lid body surface 141b may align with at least a portion of top fence body surface 131t such that at least a portion of protrusion 146a of bottom lid body surface 141b may be configured to rest within at least a portion of hole 136a of shield fence 130. Once shield lid 140 is lowered over shield fence 130 in the direction of arrow D far enough that protrusion 146a has been positioned within hole 136a, protrusion 146a may interact with a portion of fence body 132 about hole 136a to prevent or severely limit the movement of shield lid 140 with respect to shield fence 130 in at least the X-direction, and maybe also the Y-direction. Moreover, protrusion 146a and hole 136a may be sized to ensure or at least promote an interference fit or any suitable contact between protrusion 146a and a portion of fence body 132 about hole 136a. Such contact between protrusion 146a and a portion of fence body 132 about hole 136a may electrically couple shield lid 140 to shield fence 130, which may provide at least one ground point G108, and which may allow shield assembly 170 to properly shield electrical region 125. For example, a cross-section of protrusion 146a may be configured to be at least slightly larger than a cross-section of hole 136a, such that contact may be ensured between protrusion 146a and at least a portion of fence body 132 about hole 136a (e.g., at one or more ground contact points G108 as shown in FIGS. 12 and 12A).

As shown in FIGS. 8-11, at least two additional interlocking lid features 146 of shield lid 140 may be provided as dimples or protrusions extending out away from bottom lid body surface 141b of lid body 142 (e.g., protrusions 146b and 146c), and at least two additional associated interlocking fence features 136 of shield fence 130 may include holes extending at least partially through fence body 132 (e.g., holes 136b and 136c). Protrusion 146b and associated hole 136b may provide at least one ground point G107, while protrusion 146c and associated hole 136c may provide at least one ground point G109. Alternatively, shield fence 130 may include a single interlocking fence feature 136 that may interlock with two or more interlocking lid features 146. For example, in some embodiments, rather than including three distinct holes 136a, 136b, and 136c, fence body 132 may include a single groove (e.g., groove 136a′ of FIG. 8) at least partially through fence body 132 that may be configured to receive each one of protrusions 146a, 146b, and 146c. Such a configuration may allow single groove 136a′ of shield fence 130 to provide at least three ground points 107, 108, and 109 with respective protrusions 146a, 146b, and 146c of shield lid 140. In other embodiments, rather than including three distinct protrusions 146a, 146b, and 146c, fence body 142 may include a single elongated protrusion (e.g., protrusion 146a′ of FIG. 9) that may interlock with single groove 136a′ of FIG. 8. Such a configuration may allow single groove 136a′ of shield fence 130 to provide multiple ground points with protrusion 146a′ of shield lid 140.

Additionally or alternatively, as shown in FIGS. 8-11, an interlocking lid feature 146 of shield lid 140 may include a dimple or protrusion 146d extending out away from an inner lid finger surface 144i of a lid finger 144, and an associated interlocking fence feature 136 of shield fence 130 may include a slot 136d that may be formed by adjacent sides of adjacent fence fingers 134. In some embodiments, when shield lid 140 is lowered over shield fence 130 in the direction of arrow D, not only may protrusion 146a be configured to rest within hole 136a, but protrusion 146d may be configured to snap into slot 136d. In some embodiments, the interaction of protrusion 146d with slot 136d may be similar to the interaction of protrusion 146a with hole 136a (e.g., the interaction of protrusion 146d with slot 136d may limit the movement of shield lid 140 with respect to shield fence 130 in at least the

X-direction, and the interaction of protrusion 146d with slot 136d may electrically couple shield lid 140 to shield fence 130 at a ground point G111). Slot 136d may be provided in any suitable way between adjacent fence fingers 134. For example, as shown, slot 136d may not have a perimeter fully defined by fence 130 but may instead be open on at least one side (e.g., a side of slot 136d may be open and facing downward towards circuit board 90). Alternatively, slot 136d may be completely defined by fence 130 (e.g., a hole through a portion of fence 130 shared by two adjacent fence fingers 134). Additionally or alternatively, an interlocking lid feature may be defined by a portion of lid 140 shared by two adjacent lid fingers and an associated interlocking fence feature may be defined by a portion of a single fence finger or a portion of fence 130 shared by two adjacent fence fingers.

In addition to or as an alternative to interlocking one or more interlocking fence features 136 with one or more interlocking lid features 146, shield lid 140 may additionally or alternatively be coupled to shield fence 130 by ensuring contact between at least one contacting lid feature 148 of shield lid 140 with at least one respective contacting fence feature 138 of shield fence 130 when shield assembly 170 is fully assembled. A contacting fence feature 138 and an associated contacting lid feature 148 may include any suitable elements that may ensure contact between features 138 and 148 in any suitable manner for electrically coupling shield lid 140 to shield fence 130 for providing a ground point that may allow shield assembly 170 to properly shield electrical region 125 when shield assembly 170 is fully assembled. The elements of a contacting fence feature 138 and an associated contacting lid feature 148 may include any suitable elements that may appropriately ensure contact between features 138 and 148 in any suitable manner (e.g., as described above with respect to contacting features 38/48).

For example, as shown in FIGS. 8-12A, a contacting lid feature 148 of shield lid 140 may include a dimple or protrusion 148a extending out away from an inner lid finger surface 144i of a lid finger 144, and an associated contacting fence feature 138 of shield fence 130 may include a flat or substantially flat surface portion 138a along an outer fence finger surface 1340 of a fence finger 134. When shield lid 140 is lowered over shield fence 130 in the direction of arrow D, at least a portion of inner lid finger surface 144i may align with at least a portion of outer fence finger surface 134o such that protrusion 148a of shield lid 140 may be configured to initiate and maintain contact with surface portion 138a of shield fence 130. Once shield lid 140 is lowered over shield fence 130 in the direction of arrow D far enough that protrusion 148a has contacted surface portion 138a, protrusion 148a may be configured to (e.g., biased or sized to) interact with surface portion 138a of fence finger 134 to ensure and maintain suitable contact between protrusion 148a and surface portion 138a of fence finger 134 for electrically coupling shield lid 140 to shield fence 130, which may provide a ground point G115 at the point of contact that may allow shield assembly 170 to properly shield region 125. In some embodiments, a single fence finger 134 may provide a substantially continuous surface, at least a first portion of which may be provided as a first contacting fence feature 138 for contacting a first contacting lid feature 148, and at least a second portion of which may be provided as a second contacting fence feature 138 for contacting a second contacting lid feature 148.

As shown in FIGS. 8-12A, shield assembly 170 may provide eighteen ground points G101-G118 between shield fence 130 and shield lid 140, and ground points G101-G118 may together define a closed loop of ground points along/about lid 140 (e.g., a closed loop, which may extend from point G101 to adjacent point G102 to adjacent point G103, and so on, to adjacent point G117 to adjacent point G118 to adjacent point G101). In some embodiments, in order for shield assembly 170 to provide appropriate interference shielding, each particular ground point of the closed loop may not be positioned more than a maximum threshold distance away from each of the two ground points adjacent to that particular ground point in the loop. For example, in some embodiments, any two adjacent ground points in the closed loop of ground points G101-G118 provided by shield assembly 170 must be positioned within a particular threshold distance of one another (e.g., 3.0 millimeters).

However, as shown in FIGS. 8-12A, for example, shield lid 140 may not include a lid finger 144 extending downwardly from at least a portion of one side of lid body 142 (e.g., the portion of the side of lid body 142 from under which fence body 132 extends in the X-direction as shown on the right-hand side of each one of FIGS. 10, 12, and 12A). Although this may reduce the thickness of at least a portion of shield assembly 170 (e.g., along the X-direction, from a thickness T1, which may be at least equal to a thickness of lid body 142 and fence body 132, to a thickness T2, which may be equal to the thickness of fence body 132, as shown in FIG. 12A), the lack of a lid finger 144 extending adjacent any of the fence fingers 134 on that side of shield assembly 170 (e.g., fence finger 134a) may deprive those fence fingers 134 of the ability to interact with (e.g., form a ground point with) a portion of shield lid 140. Therefore, without providing the ground points between lid body 142 and fence body 132 (e.g., ground points G107-G109), the distance between ground point G106 and ground point G110 provided between associated fence fingers 134 and lid fingers 144 may exceed the maximum distance threshold between two adjacent ground points in a closed loop of ground points of shield assembly 170. Ground points G107-G109 may ensure proper shielding while also allowing the thickness and/or height (e.g., in the Z-direction) of shield assembly 170 to be reduced by not extending lid body 142 and/or lid fingers 144 of lid 140 over certain portions of fence 130.

Moreover, as shown in FIGS. 12 and 12A, extending fence 130 beyond lid 140 (e.g., in the X-direction, as shown on the right-hand side of each one of FIGS. 10, 12, and 12A) may allow shield assembly 170 to shield a taller circuitry region without increasing the height of the shield assembly. For example, as shown in FIGS. 12 and 12A, fence body 132 may be shaped such that its distance from top surface 91 of circuit board 90 may increase from a first distance Dl at a first portion of fence body 132 positioned underneath lid body 142, to a second distance D2 at a second portion of fence body 132 that extends beyond lid body 142. This may allow circuitry region 125 to include component 120d under the second portion of fence body 132 that may not have fit under the first portion of fence body 132 (e.g., component 120d may have a height H1 that may be greater than distance Dl but less than distance D2).

In some embodiments, distance D2 may be less than, greater than, or equal to a distance D3 between top surface 91 of circuit board 90 and bottom surface 141b of a portion of lid body 142 positioned over opening 139 of fence body 132 (see, e.g., distance D3 of FIG. 12).

As shown, fence body 132 may include a step portion 132a that may increase the distance of fence body 132 from circuit board 90 from distance Dl to distance D2. In some embodiments, this step portion 132a may also interact with a portion of lid 140 (e.g., an end portion 142a of lid body 142). For example, as shown in FIGS. 12 and 12A, step portion 132a may be configured to prevent end portion 142a of lid body 142 from moving in the X-direction beyond step portion 132a, which may maintain the thickness of at least a portion of shield assembly 170 at thickness T1. In some embodiments, end portion 142a and step portion 132a may be configured to contact one another and provide a ground point (e.g., a ground point G119 of FIG. 12A) when shield assembly 170 is fully assembled.

In some embodiments, as shown in FIGS. 12 and 12A only, device 10 may include a flex 180 or any other suitable circuit component that may be routed over the top of at least a portion of shield assembly 170. For example, as shown, an adhesive 184 may be provided along at least a portion of the top surface of shield assembly 170 (e.g., along at least a portion of top surface 141t of lid body 142 and at least a portion of top surface 131t of fence body 132), and flex 180 may be routed on top of at least a portion of adhesive 184, over at least a portion of shield assembly 170, and towards another device component (e.g., device component 188 of device 10 adjacent assembly 170).

Shield fence 130 and shield lid 140 of shield assembly 170 may each be formed similarly to shield fence 30 and shield lid 40 of shield assembly 70, as described above. Although each lid finger 144 of lid 140 is shown to include only a single interlocking lid feature 146 or a single contacting lid feature 148, each lid finger 144 may be provided with two or more of one or both such features, and each one of such features my interact with one or more associated features on one or more associated fence fingers 134.

Similarly, although each fence finger 134 of fence 130 is shown to include only a single interlocking fence feature 136 or a single contacting fence feature 138, each fence finger 134 may be provided with two or more of one or both such features, and each one of such features my interact with one or more associated features on one or more associated lid fingers 144.

Although lid body 142 is only shown to electrically couple with fence body 132 at ground points G107-G109 that may be positioned adjacent fence fingers 134 that do not share a ground point with a lid finger 144 (e.g., ground point G108 adjacent fence finger 134a), lid body 142 and fence body 132 may share a ground point at any other suitable position (e.g., at a point P101 of FIG. 12 that may be positioned above a fence finger 134 that may share ground point G115 with a lid finger 144). Moreover, in some embodiments, rather than providing a fence finger 134 that does not share a ground point with any lid finger 144 (e.g., fence finger 134a), shield assembly 170 may include at least one lid finger 144 that does not share a ground point with any fence finger 134. Moreover, rather than a lid finger 144 extending about fence 130 such that an inner surface 144i of the lid finger 144 may face an outer surface 134o of a fence finger 134 for sharing a ground point between the inner surface 144i and the outer surface 134o (e.g., as shown in FIGS. 10-12A), one, some, or all of the lid fingers 144 of lid 140 may be configured to extend through an opening of fence 130 (e.g., through opening 139) such that an outer surface 144o of such a lid finger 144 may face an inner surface 134i of a fence finger 134 (e.g., for sharing a ground point between the outer surface 144o and the inner surface 134i).

The size and shape of each fence body, fence finger, fence opening, lid body, lid finger, interlocking feature, and contacting feature may vary based on various factors, such as the size and shape of the electronic components of the circuitry region being shielded, the magnitude of the interference to be shielded, and the like. For example, as shown in FIGS. 1-7, the shape of shield assembly 70 formed by shield fence 30, shield lid 40, and a portion of circuit board 90 may be substantially cuboidal, while shield assembly 170 formed by shield fence 130, shield lid 140, and a portion of circuit board 90 of FIGS. 8-12A may be irregular and specific to various geometric features of device 10.

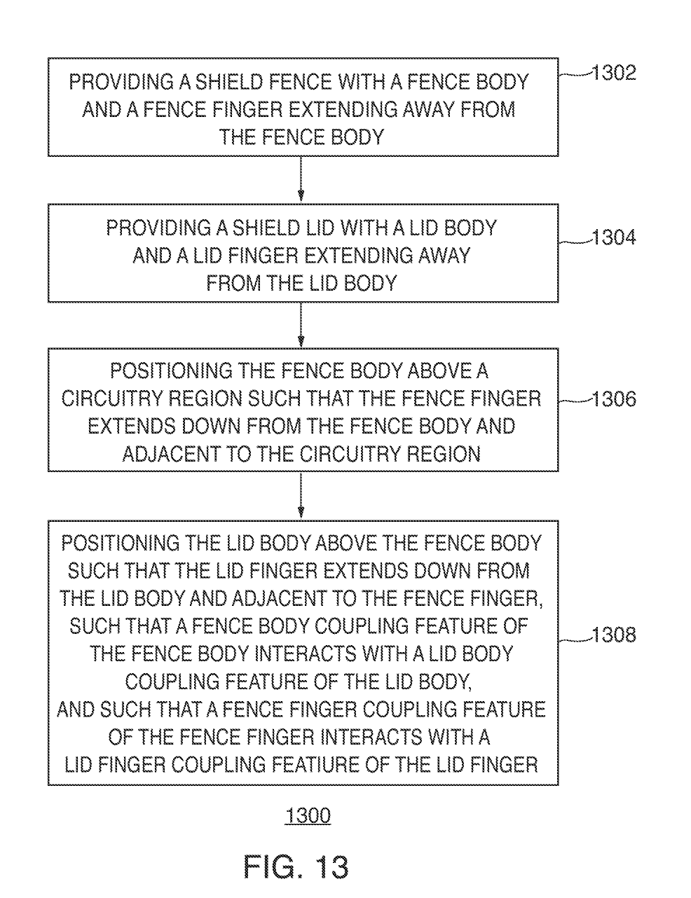

FIG. 13 is a flowchart of an illustrative process 1300 for shielding a circuitry region.

Process 1300 may include a step 1302 for providing a shield fence with a fence body and a fence finger extending away from the fence body. For example, as shown in FIGS. 1-7, shield fence 30 may include fence body 32 and at least one fence finger 34 extending away from fence body 32. Process 1300 may also include a step 1304 for providing a shield lid with a lid body and a lid finger extending away from the lid body. As also shown in FIGS. 1-7, shield lid 40 may include lid body 42 and at least one lid finger 44 extending away from lid body 42.

Next, at step 1306, process 1300 may include positioning the fence body above a circuitry region such that the fence finger may extend down from the fence body and adjacent to the circuitry region. For example, as shown in FIGS. 1-7, fence body 32 may be positioned above circuit board 90 and above circuitry region 25 (i.e., electronic component 20) such that at least one fence finger 34 may extend down from fence body 32 (e.g., in the direction of arrow D) and at least some free-end fence finger portions 35 of shield fence 30 may be coupled to top surface 91 of circuit board 90 about and/or adjacent to electronic component 20 of circuitry region 25.

Next, at step 1308, process 1300 may include positioning the lid body above the fence body such that the lid finger may extend down from the lid body and adjacent to the fence finger, such that a fence body coupling feature of the fence body may interact with a lid body coupling feature of the lid body, and such that a fence finger coupling feature of the fence finger may interact with a lid finger coupling feature of the lid finger. For example, as also shown in FIGS. 3-7, lid body 42 may be positioned above fence body 32 such that at least one lid finger 44 may extend down from lid body 42 (e.g., in the direction of arrow D) and such that an inner surface 44i of the lid finger 44 may be adjacent to and face an outer surface 34o of a fence finger 34. Moreover, as shown in FIGS. 3-7, lid body 42 may be positioned above fence body 32 such that a fence body coupling feature of fence body 32 (e.g., any interlocking fence feature 36 of fence body 32 or any contacting fence feature 38 of fence body 32) may interact with a lid body coupling feature of lid body 42 (e.g., any interlocking lid feature 46 of lid body 42 or any contacting lid feature 48 of lid body 42). For example, as shown in FIGS. 6 and 7, protrusion 48c of lid body 42 may interact with surface 38c of fence body 32 and/or protrusion 46d of lid body 42 may interact with hole 36d of fence body 32. Moreover, as shown in FIGS. 3-7, lid body 42 may be positioned above fence body 32 such that a fence finger coupling feature of a fence finger 34 (e.g., any interlocking fence feature 36 of any fence finger 34 or any contacting fence feature 38 of any fence finger 34) may interact with a lid finger coupling feature of a lid finger 44 (e.g., any interlocking lid feature 46 of any lid finger 44 or any contacting lid feature 48 of any lid finger 44). For example, as shown in FIG. 6, protrusion 36c of fence finger 34 may interact with hole 46c of lid finger 44 and/or, as shown in FIG. 7, protrusion 38d of fence finger 34 may interact with surface 48d of lid finger 44.

In some embodiments of process 1300, the circuitry region may be coupled to a top surface of a circuit board (e.g., top surface 91 of circuit board 90), for example, via solder or any other suitable technique. Process 1300 may also include coupling the fence finger (e.g., a free-end 35 of a fence finger 34 of FIGS. 1-7) to the top surface of the circuit board. Moreover, in some embodiments, after steps 1302-1308, and after coupling the fence finger to the top surface of the circuit board, process 1300 may also include repositioning the lid body even further above the fence body, such that the fence body coupling feature does not interact with the lid body coupling feature and such that the fence finger coupling feature does not interact with the lid finger coupling feature. For example, as described above with respect to FIGS. 1-7, after shield assembly 70 has been fully assembled, shield lid 40 may be removable uncoupled from shield fence 30 without impairing any of the features 36, 38, 46, or 48. In some embodiments, the repositioning of the shield lid with respect to the shield fence may uncover an opening provided through the fence body (e.g., opening 39 provided through fence body 32).

It is understood that the steps shown in FIG. 13 are merely illustrative and that existing steps may be modified, added, or omitted.

While there have been described systems and methods for shielding circuitry from interference with a removable shield assembly, it is to be understood that many changes may be made therein without departing from the spirit and scope of the invention. It is also to be understood that various directional and orientational terms such as “up” and “down,” “left” and “right,” “top” and “bottom,” and the like are used herein only for convenience, and that no fixed or absolute directional or orientational limitations are intended by the use of these words. For example, the devices of the invention can have any desired orientation. If reoriented, different directional or orientational terms may need to be used in their description, but that will not alter their fundamental nature as within the scope and spirit of the invention. Those skilled in the art will appreciate that the invention can be practiced by other than the described embodiments, which are presented for purposes of illustration rather than of limitation, and the invention is limited only by the claims which follow.

What is claimed is:

1. A shield assembly comprising:
a shield fence comprising:
a fence body comprising a fence body coupling feature; and
a fence finger extending from the fence body and comprising a fence finger coupling feature; and
a shield lid comprising:
a lid body comprising a lid body coupling feature that interacts with the fence body coupling feature to create a first ground point when the shield fence is coupled to the shield lid; and
a lid finger extending from the lid body and comprising a lid finger coupling feature that interacts with the fence finger coupling feature to create a second ground point when the shield fence is coupled to the shield lid.

2. The shield assembly of claim 1, wherein the fence finger extends perpendicularly from the fence body.

3. The shield assembly of claim 1, wherein the lid finger extends perpendicularly from the lid body.

4. The shield assembly of claim 1, wherein the fence body coupling feature and the lid body coupling feature are interlocking features.

5. The shield assembly of claim 1, wherein the fence body coupling feature and the lid body coupling feature are contacting features.

6. The shield assembly of claim 1, wherein the fence finger coupling feature and the lid finger coupling feature are interlocking features.

7. The shield assembly of claim 1, wherein the fence finger coupling feature and the lid finger coupling feature are contacting features.

8. The shield assembly of claim 1, wherein:
the shield fence further comprises a fence body opening through the fence body; and
the lid body covers the fence body opening when the shield fence is coupled to the shield lid.

9. The shield assembly of claim 1, wherein:
a plurality of ground points comprising at least the first ground point and the second ground point is created when the shield fence is coupled to the shield lid;
the plurality of ground points define a closed loop of ground points; and
each ground point of the plurality of ground points is separated by less than a threshold distance from each of the two ground points adjacent to the ground point in the closed loop.

10. The shield assembly of claim 9, wherein the threshold distance is 3 millimeters.

11. A system comprising:
a circuit board;
a circuitry region coupled to a top surface of the circuit board;
a shield fence coupled to the top surface of the circuit board, the shield fence comprising:
a fence body comprising a fence body coupling feature; and
a fence finger extending from the fence body and comprising a fence finger coupling feature; and
a shield lid comprising:
a lid body comprising a lid body coupling feature that interacts with the fence body coupling feature when the shield fence is coupled to the shield lid; and
a lid finger extending from the lid body and comprising a lid finger coupling feature that interacts with the fence finger coupling feature when the shield fence is coupled to the shield lid.

12. The system of claim 11, wherein:
at least a portion of the fence body is parallel to at least a portion of the top surface of the circuit board; and
the fence finger extends perpendicularly from the at least a portion of the fence body towards the top surface of the circuit board.

13. The system of claim 11, wherein:
at least a portion of the lid body is parallel to at least a portion of the top surface of the circuit board; and
the lid finger extends perpendicularly from the at least a portion of the lid body towards the top surface of the circuit board.

14. The system of claim 11, wherein the lid body coupling feature interacts with the fence body coupling feature to restrict the movement of the shield fence with respect to the shield lid in at least one direction when the shield fence is coupled to the shield lid.

15. The system of claim 14, wherein the at least one direction is parallel to at least a portion of the top surface of the circuit board.

16. The system of claim 14, wherein the at least one direction is parallel to at least a portion of at least one of the fence body and the lid body.

17. The system of claim 11, wherein the lid finger coupling feature interacts with the fence finger coupling feature to restrict the movement of the shield fence with respect to the shield lid in at least one direction when the shield fence is coupled to the shield lid.

18. The system of claim 17, wherein the at least one direction is perpendicular to at least a portion of the top surface of the circuit board.

19. The system of claim 17, wherein the at least one direction is perpendicular to at least a portion of at least one of the fence body and the lid body.

20. The system of claim 11, wherein:
the shield fence is fixedly attached to the top surface of the circuit board; and
the shield fence is removably coupled to the shield lid.

21. The system of claim 11, wherein:
the lid body coupling feature interacts with the fence body coupling feature to create a first ground point when the shield fence is coupled to the shield lid;
the lid finger coupling feature interacts with the fence finger coupling feature to create a second ground point when the shield fence is coupled to the shield lid;
a plurality of ground points comprising at least the first ground point and the second ground point is created when the shield fence is coupled to the shield lid;
the plurality of ground points define a closed loop of ground points; and
each ground point of the plurality of ground points is separated by less than a threshold distance from each of the two ground points adjacent to the ground point in the closed loop.

22. The system of claim 21, wherein the threshold distance is 3 millimeters.

23. A method for shielding a circuitry region, the method comprising:
providing a shield fence comprising a fence body and a fence finger extending away from the fence body;
providing a shield lid comprising a lid body and a lid finger extending away from the lid body;
positioning the fence body above the circuitry region such that the fence finger extends down from the fence body and adjacent to the circuitry region; and
positioning the lid body above the fence body such that:
the lid finger extends down from the lid body and adjacent to the fence finger;
a fence body coupling feature of the fence body interacts with a lid body coupling feature of the lid body; and
a fence finger coupling feature of the fence finger interacts with a lid finger coupling feature of the lid finger.

24. The method of claim 23, wherein:
the circuitry region is coupled to a top surface of a circuit board; and
the method further comprises coupling the fence finger to the top surface of the circuit board.

25. The method of claim 24, wherein, after the positioning the fence body, after the coupling, and after the positioning the lid body, the method further comprises repositioning the lid body even further above the fence body, such that:
the fence body coupling feature does not interact with the lid body coupling feature; and
the fence finger coupling feature does not interact with the lid finger coupling feature.

26. The method of claim 25, wherein:
the providing the shield fence comprises providing a fence body opening through the fence body;
the positioning the lid body comprises covering the fence body opening with the lid body; and
the repositioning the lid body uncovers the fence body opening.

27. The method of claim 25, wherein the repositioning the lid body does not impair any one of the fence body coupling feature, the lid body coupling feature, the fence finger coupling feature, and the lid finger coupling feature.
